(19) United States
(12) Patent Application Publication
(10) Pub. No.: US 2025/0167756 A1
(43) Pub. Date: May 22, 2025

(54) ACOUSTIC WAVE DEVICE AND FILTER DEVICE

(71) Applicant: Murata Manufacturing Co., Ltd., Nagaokakyo-shi (JP)

(72) Inventors: Takuya YABU, Nagaokakyo-shi (JP); Ryo NAKAGAWA, Nagaokakyo-shi (JP); Kentaro NAKAMURA, Nagaokakyo-shi (JP)

(21) Appl. No.: 19/007,660

(22) Filed: Jan. 2, 2025

Related U.S. Application Data
(63) Continuation of application No. PCT/JP2023/020462, filed on Jun. 1, 2023.

(30) Foreign Application Priority Data
Jul. 7, 2022 (JP) 2022-109771

(51) Int. Cl. H03H 9/02; H03H 9/13; H03H 9/56

(52) U.S. Cl. CPC H03H 9/02086; H03H 9/02015; H03H 9/132; H03H 9/568

(57) ABSTRACT

An acoustic wave device includes a piezoelectric substrate including a piezoelectric layer, and an IDT electrode on the piezoelectric layer. The IDT electrode includes first and second busbars facing each other, first electrode fingers each of which includes one end connected to the first busbar, and second electrode fingers each of which includes one end connected to the second busbar. The first and second electrode fingers are interdigitated with each other. A portion where the first and second electrode fingers overlap in an acoustic wave propagation direction is an intersecting region. A shape of the first and second electrode fingers in plan view includes a curved portion. In the intersecting region, resonant frequencies or anti-resonant frequencies are the same or substantially the same.

### CROSS REFERENCE TO RELATED APPLICATIONS

This application claims the benefit of priority to Japanese Patent Application No. 2022-109771 filed on Jul. 7, 2022 and is a Continuation Application of PCT Application No. PCT/JP2023/020462 filed on Jun. 1, 2023. The entire contents of each application are hereby incorporated herein by reference.

### BACKGROUND OF THE INVENTION

### 1. Field of the Invention

The present invention relates to acoustic wave devices and filter devices.

### 2. Description of the Relate Art

Acoustic wave devices have been widely used for filters in mobile phones and other devices. International Publication No. WO 2011/108229 discloses an example of acoustic wave devices. This acoustic wave device includes an interdigital transducer (IDT) electrode on a piezoelectric substrate. The shape of the plural electrode fingers of the IDT electrode includes a curved shape. More specifically, each electrode finger extends along a curved line from the center of the intersecting region of the IDT electrode to common electrodes.

In the IDT electrode of the acoustic wave device described in International Publication No. WO 2011/108229, the electrode finger pitch is smaller in a central portion in the direction in which the plural electrode fingers extend than in end portions in the same direction. Such a configuration has the effect of reducing unwanted wave responses. However, the resonant frequency varies from portion to portion in the IDT electrode. This can deteriorate the resonance characteristics.

### SUMMARY OF THE INVENTION

Example embodiments of the present invention provide acoustic wave devices and filter devices in each of which unwanted waves are reduced or prevented and deterioration of resonance characteristics is reduced or prevented.

An acoustic wave device according to an example embodiment of the present invention includes a piezoelectric substrate including a piezoelectric layer, and an IDT electrode on the piezoelectric layer, in which the IDT electrode includes a first busbar and a second busbar facing each other, a plurality of first electrode fingers each of which includes one end connected to the first busbar, and a plurality of second electrode fingers each of which includes one end connected to the second busbar, the plurality of first electrode fingers and the plurality of second electrode fingers are interdigitated with each other, a portion where the plurality of first electrode fingers and the plurality of second electrode fingers overlap in an acoustic wave propagation direction is an intersecting region, a shape of the pluralities of first and second electrode fingers in plan view includes a curved portion, and in the intersecting region, resonant frequencies or anti-resonant frequencies are the same or substantially the same.

An acoustic wave device according to another example embodiment of the present invention includes a piezoelectric substrate including a piezoelectric layer, and an IDT electrode on the piezoelectric layer, in which the IDT electrode includes a first busbar and a second busbar facing each other, a plurality of first electrode fingers each of which includes one end connected to the first busbar, and a plurality of second electrode fingers each of which includes one end connected to the second busbar, the plurality of first electrode fingers and the plurality of second electrode fingers are interdigitated with each other, a portion where the plurality of first electrode fingers and the plurality of second electrode fingers overlap in an acoustic wave propagation direction is an intersecting region, a shape of the pluralities of first and second electrode fingers in plan view includes a shape of a circular arc or an elliptical arc, and an electrode finger pitch decreases as an absolute value of an angle θ_{c} increases, where the angle θ_{c} is an angle between a straight line passing through a fixed point and a reference line, the fixed point being a center of a circle including the circular arc of the shape of the first and second electrode fingers or a midpoint between two foci of an ellipse including the elliptical arc, the reference line being a straight line passing through a center of the intersecting region in a direction in which the pluralities of first and second electrode fingers extend.

An acoustic wave device according to another example embodiment of the present invention includes a piezoelectric substrate including a piezoelectric layer, and an IDT electrode on the piezoelectric layer, in which the piezoelectric substrate is one of a substrate including a stack of a support substrate and the piezoelectric layer made of lithium tantalate or lithium niobate or a substrate including only the piezoelectric layer made of lithium niobate, the IDT electrode includes a first busbar and a second busbar that face each other, a plurality of first electrode fingers each of which includes one end connected to the first busbar, and a plurality of second electrode fingers each of which includes one end connected to the second busbar, the plurality of first electrode fingers and the plurality of second electrode fingers are interdigitated with each other, a portion where the plurality of first electrode fingers and the plurality of second electrode fingers overlap in an acoustic wave propagation direction is an intersecting region, a shape of the pluralities of first and second electrode fingers in plan view includes a shape of a circular arc or an elliptical arc, and the pluralities of first and second electrode fingers have one of a configuration in which an electrode finger pitch increases as an absolute value of an angle θ_{c} increases or a configuration in which the electrode finger pitch decrease as the absolute value of the angle θ_{c} increases where the angle θ_{c} is an angle between a straight line passing through a fixed point and a reference line, the fixed point being a center of a circle including the circular arc of the shape of the first and second electrode fingers or a midpoint between two foci of an ellipse including the elliptical arc, the reference line being a straight line passing through a center of the intersecting region in a direction in which the pluralities of first and second electrode fingers extend.

A filter device according to an example embodiment of the present invention includes a plurality of acoustic wave resonators, in which at least one of the acoustic wave resonators is an acoustic wave device according to an example embodiment of the present invention.

With the acoustic wave devices and the filter devices according to example embodiments of the present invention, it is possible to reduce or prevent unwanted waves and reduce or prevent deterioration of the resonance characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view along a line I-I in FIG. 1.

FIG. 3 is a schematic plan view for explaining the configuration of an IDT electrode according to the first example embodiment of the present invention.

FIG. 4 is a schematic enlarged plan view of a portion of the IDT electrode according to the first example embodiment of the present invention.

FIG. 5 is a diagram illustrating the relationship between the angle's absolute value |θ_{c}| and the duty ratio in the IDT electrode according to the first example embodiment of the present invention.

FIG. 6 is a schematic plan view of an IDT electrode according to a comparative example.

FIG. 7 is a diagram illustrating Q factors around the frequency at which the main mode is excited, in the first example embodiment of the present invention and a first comparative example.

FIG. 8 is a diagram illustrating return loss around the frequency at which Rayleigh waves occur in the first example embodiment of the present invention and the first comparative example.

FIG. 9 is a diagram illustrating slowness curves of acoustic waves propagating in a first piezoelectric substrate and a second piezoelectric substrate.

FIG. 10 is a diagram illustrating slowness curves of longitudinal waves, fast transversal waves, and slow transversal waves in the first piezoelectric substrate.

FIG. 11 is a diagram illustrating the relationship between the angle's absolute value |θ_{c}| and the duty ratio in the IDT electrode according to a first modification of the first example embodiment of the present invention.

FIG. 12 is a diagram illustrating impedance-frequency characteristics when resonant frequencies are the same or substantially the same and the difference Δf between the resonant frequencies is a negative value and when the difference Δf between the resonant frequencies is zero.

FIG. 13 is a diagram illustrating impedance-frequency characteristics when resonant frequencies are the same or substantially the same and the difference Δf between the resonant frequencies is a positive value and when the difference Δf between the resonant frequencies is zero.

FIG. 14 is a diagram illustrating the relationship between the angle's absolute value |θ_{c}| and the duty ratio in the IDT electrode according to a second modification of the first example embodiment of the present invention.

FIG. 15 is a diagram illustrating return loss around a frequency at which a higher-order mode occurs in the second modification of the first example embodiment of the present invention and the first comparative example.

FIG. 16 is a diagram illustrating the relationship between the offset electrode length and the impedance ratio.

FIG. 17 is a diagram illustrating the relationship between the gap width and the impedance ratio.

FIG. 18 is a schematic elevational cross-sectional view of an acoustic wave device according to a third modification of the first example embodiment of the present invention.

FIG. 19 is a schematic elevational cross-sectional view of an acoustic wave device according to a fourth modification of the first example embodiment of the present invention.

FIG. 20 is a schematic plan view of an acoustic wave device according to a second example embodiment of the present invention.

FIG. 21 is a schematic plan view for explaining the configuration of an IDT electrode according to the second example embodiment of the present invention.

FIG. 22 is a diagram illustrating the relationship between the angle's absolute value |θ_{c}| and the electrode finger pitch in the IDT electrode according to the second example embodiment of the present invention.

FIG. 23 is a diagram illustrating return loss around a frequency at which a higher-order mode occurs in the second example embodiment of the present invention and the first comparative example.

FIG. 24 is a schematic plan view of an acoustic wave device according to a third example embodiment of the present invention.

FIG. 25 is a schematic plan view of an acoustic wave device according to a fourth example embodiment of the present invention.

FIG. 26 is a diagram illustrating impedance-frequency characteristics in the first and fourth example embodiments of the present invention.

FIG. 27 is a diagram illustrating impedance-frequency characteristics around the upper end of the stop band in the first and fourth example embodiments of the present invention.

FIG. 28 is a diagram illustrating return loss in the first and fourth example embodiments of the present invention.

FIG. 29 is a schematic plan view of an acoustic wave device according to a fifth example embodiment of the present invention.

FIG. 30 is a diagram illustrating impedance-frequency characteristics in the first and fifth example embodiments of the present invention.

FIG. 31 is a diagram illustrating phase characteristics around 2.2 times the resonant frequency in the first and fifth example embodiments of the present invention.

FIG. 32 is a diagram illustrating return loss in the first and fifth example embodiments of the present invention.

FIG. 33 is a diagram illustrating the relationship between the angle's absolute value |θ_{c}| and the electrode finger thickness in the IDT electrode according to a sixth example embodiment of the present invention.

FIG. 34 is a schematic elevational cross-sectional view of an acoustic wave device according to a seventh example embodiment of the present invention.

FIG. 35 is a diagram illustrating the relationship between the angle's absolute value |θ_{c}| in a portion of the IDT electrode covered with dielectric film and the thickness of the dielectric film in the seventh example embodiment of the present invention.

FIG. 36 is a diagram illustrating the relationship between the angle's absolute value |θ_{c}| in a portion of the IDT electrode covered with dielectric film and the thickness of the dielectric film in a modification of the seventh example embodiment of the present invention.

FIG. 37 is a schematic plan view of an acoustic wave device according to an eighth example embodiment of the present invention.

FIG. 38 is a schematic plan view of areas around a first edge section and a second edge section in an acoustic wave device according to a ninth example embodiment of the present invention.

FIG. 39 is schematic plan views of areas around a first edge section and a second edge section in an acoustic wave device according to a 10th example embodiment of the present invention.

FIG. 40 is a circuit diagram of a filter device according to an 11th example embodiment of the present invention.

FIG. 41 is a schematic enlarged plan view of a portion of an IDT electrode according to a fifth modification of the first example embodiment of the present invention.

FIG. 42 is a schematic elevational cross-sectional view of an acoustic wave device according to a 12th example embodiment of the present invention.

FIG. 43 is a schematic elevational cross-sectional view of an acoustic wave device according to a 13th example embodiment of the present invention.

FIG. 44 is a schematic elevational cross-sectional view of an acoustic wave device according to a first modification of the 13th example embodiment of the present invention.

FIG. 45 is a schematic elevational cross-sectional view of an acoustic wave device according to a second modification of the 13th example embodiment of the present invention.

FIG. 46 is a schematic elevational cross-sectional view of an acoustic wave device according to a third modification of the 13th example embodiment of the present invention.

### DETAILED DESCRIPTION OF THE EXAMPLE EMBODIMENTS

Hereinafter, the present invention will be disclosed in detail by describing specific example embodiments of the present invention with reference to the drawings.

Each example embodiment described in this specification is illustrative and partial substitutions or combinations of configurations are possible across different example embodiments.

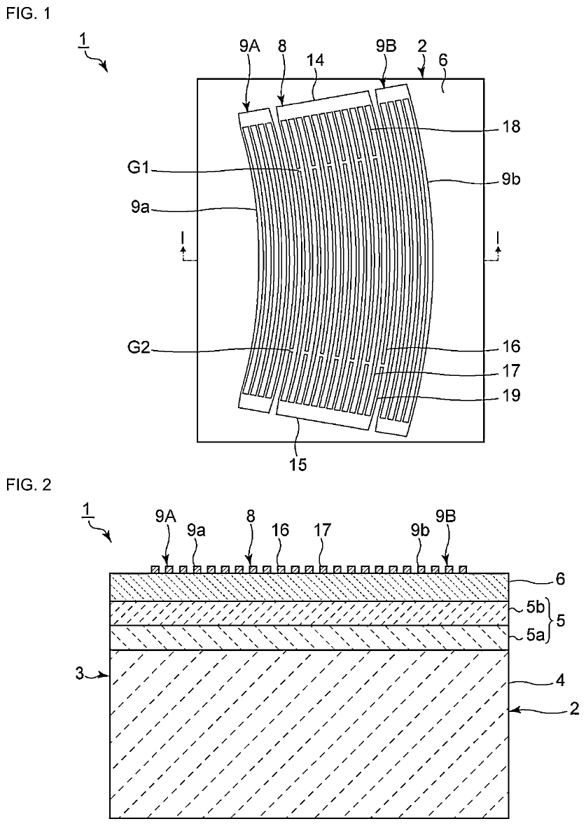

FIG. 1 is a schematic plan view of an acoustic wave device according to a first example embodiment of the present invention. FIG. 2 is a schematic cross-sectional view along a line I-I in FIG. 1.

As illustrated in FIGS. 1 and 2, an acoustic wave device 1 includes a piezoelectric substrate 2. The piezoelectric substrate 2 is a substrate having piezoelectric properties. As illustrated in FIG. 2, the piezoelectric substrate 2 includes a support 3 and a piezoelectric layer 6. More specifically, the support 3 includes a support substrate 4 and a dielectric layer 5. The dielectric layer 5 includes a first layer 5a and a second layer 5b. The first layer 5a is provided on the support substrate 4. The second layer 5b is provided on the first layer 5a. The piezoelectric layer 6 is provided on the second layer 5b. The layer structure of the piezoelectric substrate 2 is not limited to the above. For example, the piezoelectric substrate 2 may be a substrate including only the piezoelectric layer 6.

As illustrated in FIG. 1, an IDT electrode 8 is provided on the piezoelectric layer 6. The IDT electrode 8 includes plural first electrode fingers 16 and plural second electrode fingers 17. In the first example embodiment, the shape of the plural first electrode fingers 16 and the plural second electrode fingers 17 in plan view is, for example, a circular arc. In this specification, plan view refers to a view from the direction corresponding to the upper side in FIG. 2. In FIG. 2, for example, of the piezoelectric layer 6 side and the support substrate 4 side, the piezoelectric layer 6 side is the upper side. The shape of the plural first electrode fingers 16 and the plural second electrode fingers 17 in plan view only needs to include a curved portion. The shape of the plural first electrode fingers 16 and the plural second electrode fingers 17 in plan view preferably includes the shape of a circular or elliptical arc as in the first example embodiment. Hereinafter, the configuration of the IDT electrode 8 will be described in detail.

Back to FIG. 1, in addition to the plural first electrode fingers 16 and second electrode fingers 17, the IDT electrode 8 includes a first busbar 14, a second busbar 15, plural first offset electrodes 18, and plural second offset electrodes 19. The first busbar 14 and the second busbar 15 face each other. One end portion of each of the plural first electrode fingers 16 is connected to the first busbar 14. One end portion of each of the plural second electrode fingers 17 is connected to the second busbar 15. The plural first electrode fingers 16 and the plural second electrode fingers 17 are interdigitated with each other. The region where the first electrode fingers 16 and the second electrode fingers 17 overlap in the acoustic wave propagation direction is referred to as an intersecting region. The first and second electrode fingers 16 and 17 are sometimes just referred to as electrode fingers hereinafter.

In other words, the intersecting region is the region between a first envelope, which is a virtual line connecting the tips of the second electrode fingers 17, and a second envelope, which is a virtual line connecting the tips of the plural first electrode fingers 16. More specifically, the intersecting region is the region surrounded by the first envelope, the second envelope, the electrode finger at one end of the plural electrode fingers in the direction in which the plural electrode fingers are aligned, and the electrode finger at the other end. The first envelope corresponds to an edge portion of the intersecting region on the first busbar 14 side. The second envelope corresponds to an edge portion of the intersecting region on the second busbar 15 side.

One end portion of each of the plural first offset electrodes 18 is connected to the first busbar 14. The first electrode fingers 16 and the first offset electrodes 18 are alternately aligned. One end portion of each of the plural second offset electrodes 19 is connected to the second busbar 15. The second electrode fingers 17 and the second offset electrodes 19 are alternately aligned.

The plural first electrode fingers 16, the plural second electrode fingers 17, the plural first offset electrodes 18, and the plural second offset electrodes 19 each include a proximal end portion and a distal end portion. The proximal end portions of the first electrode fingers 16 and first offset electrodes 18 are connected to the first busbar 14. The proximal end portions of the second electrode fingers 17 and second offset electrodes 19 are connected to the second busbar 15. The distal end portions of the first electrode fingers 16 face the respective distal end portions of the second offset electrodes 19 across gaps G2. Furthermore, the distal end portions of the first electrode fingers 16 face the second busbar 15 across the gaps G2 and the second offset electrodes 19. On the other hand, the distal end portions of the second electrode fingers 17 face the respective distal end portions of the first offset electrodes 18 across gaps G1. Furthermore, the distal end portions of the second electrode fingers 17 face the first busbar 14 across the gaps G1 and the first offset electrodes 18.

In the following description, the first and second offset electrodes 18 and 19 may be simply referred to as offset electrodes. The first and second busbars 14 and 15 may be simply referred to as busbars.

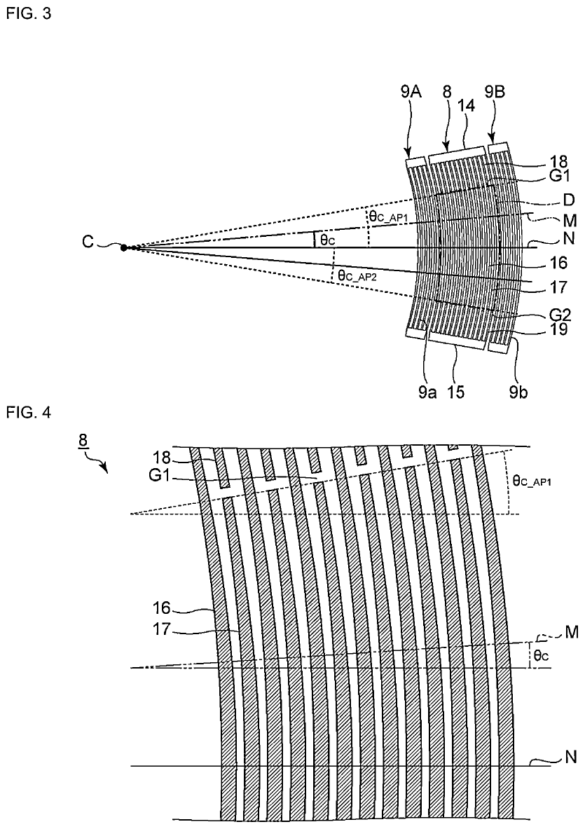

FIG. 3 is a schematic plan view for explaining the configuration of the IDT electrode according to the first example embodiment.

The plural electrode fingers have shapes corresponding to, for example, circular arcs of different concentric circles in plan view. The centers of circles including the circular arcs of the shapes of the plural electrode fingers are therefore coincident. The centers are referred to as a fixed point C. In the first example embodiment, the edge portion of the intersecting region D on the first busbar 14 side is adjacent to the plural gaps G1. The edge portion of the intersecting region D on the second busbar 15 side is adjacent to the plural gaps G2.

The elliptical coefficient of a circle or an ellipse including the arc of the shape of each of the plural electrode fingers is denoted by α2/α1. The elliptical coefficient α2/α1 is, for example, about 1 in the first example embodiment. The elliptical coefficient α2/α1 is other than about 1 when the shape of the plural electrode fingers including the arc is elliptical. Herein, α1 corresponds the dimension of the ellipse along its major or minor axis that passes through the intersecting region D while α2 corresponds to the dimension of the ellipse along its major or minor axis that does not pass through the intersecting region D.

The straight line passing through the center of the intersecting region D in the direction in which the plural first electrode fingers 16 and the plural second electrode fingers 17 extend is referred to as a reference line N. Herein, the direction in which the plural first electrode fingers 16 and the plural second electrode fingers 17 extend means the direction in which the plural first electrode fingers 16 and the plural second electrode fingers 17 extend in a curve. Alternatively, the reference line N is a straight line passing through the center of the intersecting region D along the shortest line that connects the edge portions of the intersecting region D on the first busbar 14 side and the second busbar 15 side. In the first example embodiment, the reference line N is the straight line corresponding to the axis of symmetry with respect to which the edge portions of the intersecting region D on the first busbar 14 side and the second busbar 15 side are symmetric. The fixed point C is positioned on the reference line N outside the intersecting region D.

The angle between a straight line passing through the fixed point C and the reference line N is denoted by θ_{c}. There are an infinite number of straight lines passing through the fixed point C, and FIG. 3 illustrates examples of such straight lines. In this specification, the positive direction of the angle θ_{c} is the counterclockwise direction in plan view. More specifically, the positive direction corresponds to the direction from the second busbar 15 toward the first busbar 14.

When alternating-current voltage is applied to the IDT electrode 8, acoustic waves are excited in the intersecting region D. The intersecting region D includes portions located on the infinite number of straight lines passing through the fixed point C. FIG. 3 illustrates a straight line M as an example of the infinite number of straight lines passing through the fixed point C and intersecting region D. For example, acoustic waves are excited in the portion located on the straight line M within the intersecting region D. Acoustic waves are also excited in each portion located on the infinite number of other, not-illustrated straight lines within the intersecting region D. That is, each straight line passing through the fixed point C and intersecting region D is parallel or substantially parallel to the direction in which acoustic waves are excited (the direction vertical or substantially vertical to the direction in which the electrode fingers of the IDT electrode 8 extend) when the elliptical coefficient α2/α1 is about 1 and is inclined from the direction in which acoustic waves are excited when the elliptical coefficient α2/α1 is other than about 1. The direction in which the electrode fingers extend refers to the direction in which each portion of the electrode fingers extends. The acoustic wave propagation direction is parallel or substantially parallel to the direction vertical to tangents of the curved electrode fingers. The angle θ_{c} between the reference line N and a straight line passing through the fixed point C and intersecting region D is an excitation angle θ_{c_prop}. The excitation angle θ_{c_prop} is about 0 degrees in the portion on the reference line N.

The piezoelectric layer 6 of the acoustic wave device 1 is made of a piezoelectric single crystal. In the piezoelectric layer 6, the propagation axis extends in the X-propagation direction. In the first example embodiment, the propagation axis and the reference line N extend in parallel. In the acoustic wave device 1, therefore, the angle θ_{c} is an angle between a straight line passing through the fixed point C and the propagation axis. The direction of the propagation axis is not limited to the X-propagation direction and may be, for example, the about 90° X-propagation direction. Alternatively, the propagation axis may extend in the direction vertical or substantially vertical to any of the directions in which the electrode fingers of the IDT electrode 8 extend. The directions in which the electrode fingers extend herein refer to the direction in which the tangent of each portion of the electrode fingers extends.

The angle θ_{c} between the reference line N and the straight line that passes through the fixed point C and the edge portion of the intersecting region D on the first busbar 14 side is referred to as an intersection angle θ_{c_AP1}. The angle θ_{c} between the reference line N and the straight line passing through the fixed point C and the edge portion of the intersecting region D on the second busbar 15 side is referred to as an intersection angle θ_{c_AP2}. In this case, for example, θ_{c_AP2}≤θ_{c}≤θ_{c_AP1}. In the first example embodiment, the intersection angles θ_{c_AP1} and θ_{c_AP2} have the same or substantially the same absolute value. The absolute value of the angle θ_{c} satisfies: 0°≤|θ_{c}|≤|θ_{c_AP1}|=|θ_{c_AP2}|.

In the IDT electrode 8, the edge portion of the intersecting region D on the first busbar 14 side, the virtual line connecting the plural gaps G1, and the first busbar 14 extend in parallel or substantially in parallel. The edge portion of the intersecting region D on the second busbar 15 side, the virtual line connecting the plural gaps G2, and the second busbar 15 extend in parallel or substantially in parallel in similar manner.

A pair of reflectors 9A and 9B are provided on the piezoelectric layer 6. The reflectors 9A and 9B face each other across the IDT electrode 8 in the direction in which the propagation axis extends. The reflector 9A includes plural electrode fingers 9a. The reflector 9B includes plural electrode fingers 9b. In plan view, the plural electrode fingers 9a of the reflector 9A and the plural electrode fingers 9b of the reflector 9B have shapes corresponding to circular arcs of plural concentric circles. The centers of the circles including the circular arcs of the shapes of the plural electrode fingers 9a and 9b are coincident with the fixed point C.

FIG. 4 is a schematic enlarged plan view of a part of the IDT electrode according to the first example embodiment. FIG. 4 illustrates the IDT electrode 8 by hatching.

In the IDT electrode 8, the duty ratio varies according to the angle θ_{c}. More specifically, the duty ratio decreases as the absolute value of the angle θ_{c} increases. This allows resonant frequencies to be the same or substantially the same at any angle θ_{c} within the intersecting region D. Anti-resonant frequencies within the intersecting region D may be the same or substantially the same. In this specification, the phrase “one frequency is the same or substantially the same as the other frequency” means that the absolute value of the difference between these two frequencies is, for example, less than or equal to about 2% of reference frequency. In other words, the phrase “two frequencies are the same or substantially the same” means that the absolute value of the frequency variation rate is, for example, less than or equal to about 2%. The frequency variation rate is the ratio of the difference between the two frequencies to the reference frequency. The reference frequency is the frequency where the angle θ_{c} is about 0°.

The electrode finger pitch is constant in the IDT electrode 8 of the acoustic wave device 1. Wavelength λ, which is the wavelength defined by the electrode finger pitch, is therefore constant in the IDT electrode 8 irrespective of the angle θ_{c}. The electrode finger pitch refers to the distance between the centers of adjacent electrode fingers.

In the first example embodiment, resonant frequencies are the same or substantially the same at any angle θ_{c} within the intersecting region D. Such a configuration reduces or prevents unwanted waves and reduces or prevents deterioration in resonance characteristics. The details thereof will be described with the details of the configuration of the first example embodiment below.

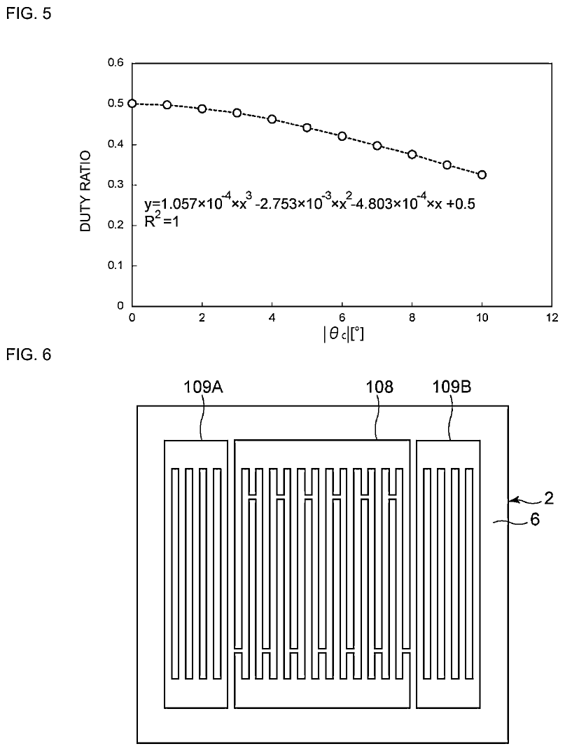

FIG. 5 is a diagram illustrating the relationship between the angle's absolute value |θ_{c}| and the duty ratio in the IDT electrode according to the first example embodiment.

In the IDT electrode 8 of the first example embodiment, the duty ratio is about 0.5 in the portion where the angle θ_{c} is about 0° as illustrated in FIG. 5. The duty ratio decreases as the angle's absolute value |θ_{c}| increases. More specifically, for example, in the first example embodiment, the following equation is satisfied: y=1.057×10⁻⁴×x³−2.753×10⁻³×x²−4.803×10⁻⁴×x+0.5 where x is the angle's absolute value |θ_{c}| and y is the duty ratio. This allows the resonant frequencies to be the same or substantially the same at any angle θ_{c} within the intersecting region D.

Herein, the frequency variation rate is defined as Δf/f_{c0}×100 where Δf is the difference in frequency between the portion where the absolute value of the angle θ_{c} is the maximum and the portion where the angle θ_{c} is about 0° and f_{c0} is the frequency in the portion where the angle θ_{c} is about 0°. The absolute value of the frequency variation rate is |Δf|/f_{C0}×100. For the resonant frequencies, |Δf|/f_{C0}×100≤2% in the first example embodiment. In more detail, Δf=f_{c_AP}−f_{c0} where f_{c_AP} is the frequency in the portion at θ_{c}=θ_{c_AP1} or θ_{c}=θ_{c_AP2}, where the absolute value of the angle θ_{c} is the maximum. In the first example embodiment, |f_{c_AP}−f_{C0}|/f_{C0}×100≤2%.

The design parameters for the acoustic wave device 1, in which the relationship between the angle's absolute value |θ_{c}| and the duty ratio have the relationship illustrated in FIG. 5, are as follows.

Support substrate 4: material, Si; plane orientation, (111); p in Euler angles (φ, θ, ψ), about 73°
First layer 5a: material, SiN; thickness, about 50 nm
Second layer 5b: material, SiO₂; thickness, about 300 nm
Piezoelectric layer 6: material, 55° rotated Y-cut X-propagation LiTaO₃; thickness, about 400 nm
IDT electrode 8: material, Al; thickness, about 100 nm
Number of pairs of electrode fingers: 60 pairs
Elliptical coefficient α2/α1 of electrode finger shape: about 1
Intersection angle: θ_{c_AP1}, about 10°; θ_{c_AP2}, about −10°
Wavelength λ: about 2 μm
Reflectors 9A and 9B: number of pairs of electrode fingers, 20 pairs

In the first example embodiment, it is possible to reduce or prevent transverse modes and Rayleigh waves as unwanted waves. This will be described by comparing the first example embodiment with a first comparative example. In this comparison, the design parameters of the acoustic wave device 1 of the first example embodiment are as described above.

In the first comparative example, electrode fingers of an IDT electrode 108 and reflectors 109A and 109B are linear as illustrated in FIG. 6. The intersecting region of the IDT electrode 108 is rectangular or substantially rectangular. An intersecting width is, for example, about 41.5λ. The intersecting width is the dimension of the intersecting region in an electrode finger extension direction, which is the direction in which the plural electrode fingers extend. The IDT electrode 108 includes, for example, 60 pairs of electrode fingers, and the reflectors 109A and 109B each include 20 pairs of electrode fingers. In the IDT electrode 108, the duty ratio is, for example, about 0.5.

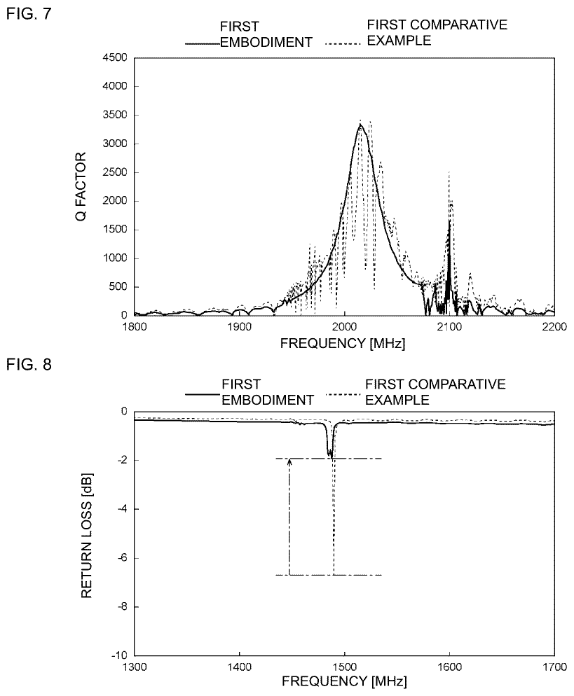

FIG. 7 is a diagram illustrating Q factors around the frequency at which the main mode is excited in the first example embodiment and the first comparative example. FIG. 8 is a diagram illustrating return loss around the frequency at which Rayleigh waves occur in the first example embodiment and the first comparative example.

In the first comparative example, large ripples are caused in the frequency characteristics of the Q factor as illustrated in FIG. 7. The ripples are due to transverse modes. In contrast, the ripples due to transverse modes are reduced or prevented in the first example embodiment. FIG. 8 reveals that Rayleigh waves as unwanted waves are significantly reduced or prevented in the first example embodiment compared to the first comparative example. Thus, unwanted waves can be reduced or prevented in the first example embodiment.

In the first example embodiment, the plural electrode fingers have different lengths. The phases of transverse modes occurring in different portions of the IDT electrode 8 are therefore unlikely to be aligned. This can reduce or prevent transverse modes from increasing in intensity as a whole, thus reducing or preventing transverse modes. Furthermore, in the first example embodiment, the electrode fingers have shapes varying in curvature in plan view. This leads to dispersion of frequencies at which Rayleigh waves occur. Rayleigh waves can therefore be reduced or prevented.

The IDT electrode 8 needs to include, for example, at least two first electrode fingers 16 or two second electrode fingers 17 varying in curvature. In other words, the IDT electrode 8 needs to include two or more electrode fingers varying in curvature in total. Such a configuration can reduce or prevent Rayleigh waves more reliably.

As described above, the resonant frequencies are the same or substantially the same in each portion in the first example embodiment. The main mode is therefore suitably excited, and the resonance characteristics can be reduced or prevented from deteriorating. The plural first electrode fingers 16 and the plural second electrode fingers 17 may gradually vary in curvature from one side toward the other in the direction in which the plural first electrode fingers 16 and the plural second electrode fingers 17 are aligned.

Example embodiments of the present invention use the propagation characteristics of acoustic waves, which are different at each angle θ_{c}. The details thereof will be described below.

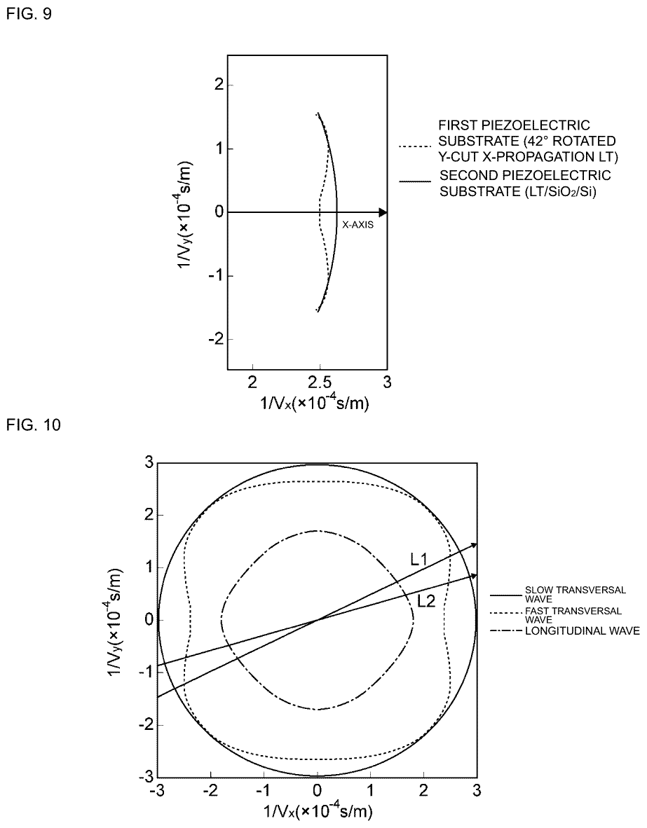

The phase velocity of acoustic waves depends on the angle θ_{c} and has characteristics specific to the configuration of the substrate. The reciprocal of phase velocity corresponds to a slowness curve. The relationship between the angle θ_{c} and the phase velocity is therefore equal or approximately equal to the slowness curve of the piezoelectric substrate. FIG. 9 illustrates slowness curve examples of piezoelectric substrates having different layer structures. One of the piezoelectric substrates is a substrate made of, for example, only 42° rotated Y-cut X-propagation LiTaO₃ (LT). This substrate is a first piezoelectric substrate. The other piezoelectric substrate is a piezoelectric layer/support substrate bonded substrate. This substrate is a second piezoelectric substrate. More specifically, the second piezoelectric substrate is, for example, a substrate including a silicon substrate of (100) orientation, a silicon oxide film, and a lithium tantalate layer laminated in this order.

FIG. 9 is a diagram illustrating slowness curves of acoustic waves propagating in the first and second piezoelectric substrates.

The slowness curves of the first and second piezoelectric substrates are each symmetric or substantially symmetric with respect to x-axis as the axis of symmetry. The direction of x-axis corresponds to the direction whose angle θ_{c} of about 0°. The slowness curve of the first piezoelectric substrate is concave while the slowness curve of the second piezoelectric substrate is convex. The dependence of acoustic waves propagating in a substrate on the angle θ, depends on the substrate structure as described above. Furthermore, the dependence of acoustic waves propagating in the same substrate on the angle θ_{c} varies according to the mode of acoustic waves. This will be described with FIG. 10.

FIG. 10 is a diagram illustrating slowness curves of longitudinal waves, fast transversal waves, and slow transversal waves in the first piezoelectric substrate.

As illustrated in FIG. 10, the slowness curves of longitudinal waves, fast transversal waves, and slow transversal waves, which are three modes of acoustic waves, are different from each other. Portions passing through arrows L1 and L2 in FIG. 10 correspond to examples in which the angle θ_{c} is other than about 0°. The distance between the slowness curves of slow transversal waves and fast transversal waves in the portion passing through the arrow L1 is different from the distance between the slowness curves of slow transversal waves and fast transversal waves in the portion passing through the arrow L2. In a similar manner, the distance between the slowness curves of fast transversal waves and longitudinal waves in the portion passing through the arrow L1 is different from the distance between the slowness curves of fast transversal waves and longitudinal waves in the portion passing through the arrow L2. That is, the distance between slowness curves of different modes varies according to the angle θ_{c}. The same applies to the relationship between the main mode used in the acoustic wave device and unwanted waves.

The resonant frequencies of the main mode are the same or substantially the same at each angle θ_{c} in the first example embodiment. Therefore, frequencies of unwanted waves are different at each angle θ_{c}, resulting in dispersion and reduction or prevention of unwanted waves.

The configuration that allows the resonant frequencies of the main mode to be the same or substantially the same will be described in detail below. The phase velocity corresponds to the reciprocal of the slowness curve as described above. The relationship between the angle θ_{c} and the phase velocity is equal or approximately equal to the slowness curve in X-Y plane of the piezoelectric substrate as illustrated in FIG. 10. This means that the function representing the curved shape of the electrode fingers is determined based on the shape of the slowness curve in X-Y plane of the piezoelectric substrate. The phase velocity of acoustic waves depends on the angle θ_{c}.

However, simply changing the shape of the electrode fingers to a curved shape will result in the impedance-frequency characteristics being a superimposition of characteristics that are greatly different in resonant frequency at each angle θ_{c}. The impedance-frequency characteristics will be significantly deteriorated. Therefore, the duty ratio, which affects frequency, is varied according to the angle θ_{c} like the first example embodiment, so that the frequencies of acoustic waves excited at each angle θ_{c} can be made the same or substantially the same. The resonant frequencies can thus be the same or substantially the same at each angle θ_{c}. The anti-resonant frequencies can be also the same or substantially the same at each angle θ_{c}. This results in impedance-frequency characteristics in which the resonant or anti-resonant frequencies are the same or substantially the same.

Not limited to the duty ratio, parameters, such as the electrode finger pitch affecting frequency, the thickness of the electrode fingers, the thickness of the piezoelectric layer, and the thickness of an intermediate layer in the piezoelectric substrate, may be varied according to the angle θ_{c}. The intermediate layer is a dielectric layer, for example. When a dielectric film is provided on the piezoelectric substrate so as to cover the IDT electrode, the thickness of the dielectric film may vary according to the angle θ_{c}. Even in such a case, the resonant or anti-resonant frequencies can be the same or substantially the same at each angle θ_{c}. When the dielectric layer is provided on the piezoelectric substrate so as to cover the IDT electrode, parameters other than the thickness of the dielectric film may vary according to the angle θ_{c}. In this case, the thickness of the dielectric film may be constant.

In the acoustic wave device described in International Publication No. WO 2011/108229, the slowness curve is concave. In this IDT electrode, even if the electrode finger pitch is configured to be narrower in the central portion in the direction in which the plural electrode fingers extend than in the end portions in the same direction to reduce or prevent responses of unwanted waves, variations in resonant frequencies across different portions of the IDT electrode will deteriorate the resonance characteristics. In contrast, in the first example embodiment, the slowness curve is convex. The resonant frequencies within the intersecting region can therefore be made the same or substantially the same by decreasing the duty ratio as the absolute value of the angle θ_{c} increases.

The anti-resonant frequencies may be the same or substantially the same at each angle θ_{c} within the intersecting region as described above. An example thereof will be described as a first modification of the first example embodiment. This modification is different from the first example embodiment only in the relationship between the angle θ_{c} and the duty ratio. The description of the first modification will incorporate reference numerals used in the description of the first example embodiment.

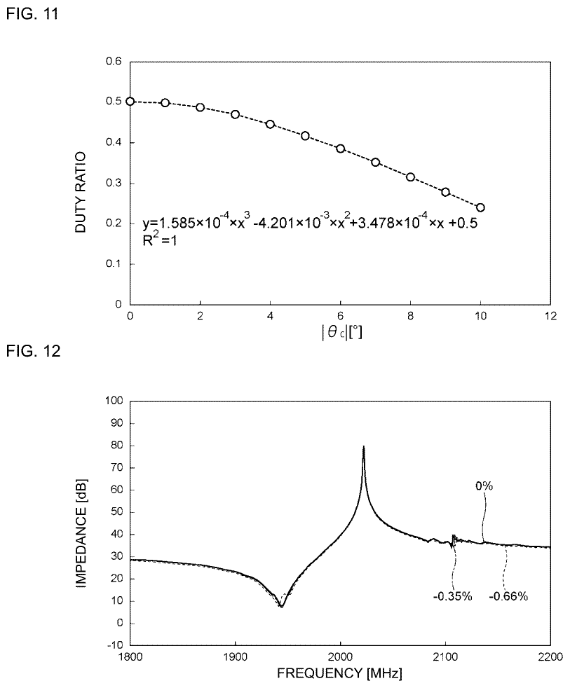

FIG. 11 is a diagram illustrating the relationship between the angle's absolute value |θ_{c}| and the duty ratio in the IDT electrode according to the first modification of the first example embodiment.

In the IDT electrode 8 of the first modification of the first example embodiment, the duty ratio is, for example, about 0.5 in the portion where the angle θ_{c} is about 0° as illustrated in FIG. 11. The duty ratio decreases as the angle's absolute value |θ_{c}| increases. More specifically, in the first modification, the following equation is satisfied: y=1.585×10⁻⁴×x³−4.201×10⁻³×x²+3.478×10⁻⁴×x+0.5 where x is the angle's absolute value |θ_{c}| and y is the duty ratio. This allows the anti-resonant frequencies to be the same or substantially the same at any angle θ, within the intersecting region D. Even in the first modification, therefore, it is possible to reduce or prevent unwanted waves and reduce or prevent deterioration of the resonance characteristics.

For the resonant or anti-resonant frequencies, the absolute value of the frequency variation rate |Δf|/f_{C0}×100 is, for example, preferably less than or equal to about 1%. This can reduce or prevent deterioration of the resonance characteristics more reliably. For the resonant or anti-resonant frequencies, more preferably, for example, the frequency variation rate Δf/f_{C0}×100 is greater than or equal to about −0.66% and less than or equal to about 0.82%. This can reduce or prevent deterioration of the resonance characteristics still more reliably. Hereinafter, an example will be illustrated in which deterioration of the resonance characteristics is reduced or prevented when about −0.66%≤Δf/f_{C0}×100 about 0.82% is satisfied for the resonant frequencies.

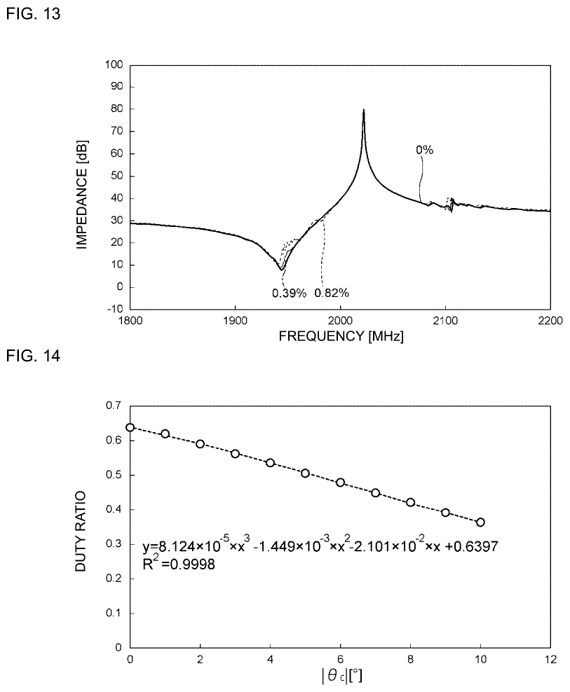

FIG. 12 is a diagram illustrating impedance-frequency characteristics when the resonant frequencies are the same or substantially the same and the difference Δf between the resonant frequencies is a negative value and when the difference Δf between the resonant frequencies is about 0. FIG. 13 is a diagram illustrating impedance-frequency characteristics when the resonant frequencies are the same or substantially the same and the difference Δf between the resonant frequencies is a positive value and when the difference Δf between the resonant frequencies is about 0.

FIG. 12 reveals that, in both cases where Δf/f_{C0}×100=about −0.35% and where Δf/f_{C0}×100=about −0.66%, the characteristics around the resonant frequencies is not greatly deteriorated compared to the case where Δf/f_{C0}×100=about 0%. In a similar manner, FIG. 13 reveals that, in both cases where Δf/f_{C0}×100=about 0.39% and where Δf/f_{C0}×100=about 0.82%, the characteristics around the resonant frequencies is not greatly deteriorated compared to the case where Δf/f_{C0}×100=about 0%.

The maximum value of the duty ratio is, for example, about 0.5 in the first example embodiment. However, the maximum value of the duty ratio is not limited to the above. The maximum value of the duty ratio is, for example, about 0.65 in a second modification of the first example embodiment. In the second modification, the angle θ_{c} and the duty ratio have a relationship illustrated in FIG. 14. The resonant frequencies are therefore the same or substantially the same at any angle θ_{c} within the intersecting region D. More specifically, the following equation is satisfied: y=8.124×10⁻⁵×x³−1.449×10⁻³×x²−2.101×10⁻²×x+0.6397 in the second modification where x is the angle's absolute value |θ_{c}| and y is the duty ratio.

In the second modification of the first example embodiment, it is possible to reduce or prevent unwanted waves and reduce or prevent deterioration of the resonance characteristics, similar to the first example embodiment. In the second modification, higher-order modes can be reduced or prevented in addition to transverse modes and Rayleigh waves. This advantageous effect will be described in detail below. The second modification will be compared with the first comparative example illustrated in FIG. 6.

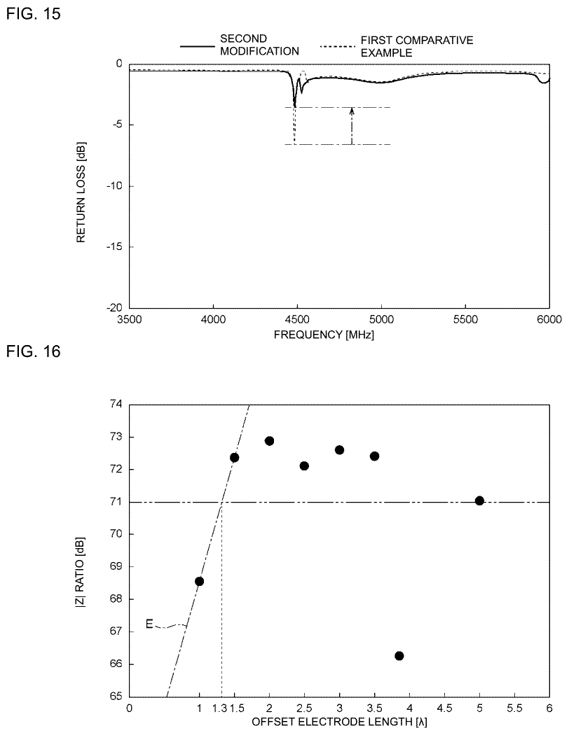

FIG. 15 is a diagram illustrating return loss around frequencies at which higher-order modes occur in the second modification of the first example embodiment and the first comparative example.

FIG. 15 reveals that higher-order modes are reduced or prevented in the second modification compared to the first comparative example. More specifically, in the second modification, higher-order modes around twice the frequency at which the main mode is excited can be reduced or prevented. The relationship between the duty ratio and the frequency of each mode varies according to the slowness curve of the piezoelectric substrate. With a certain configuration of the piezoelectric substrate or with a certain configuration on the piezoelectric substrate, the resonant frequencies or anti-resonant frequencies are the same or substantially the same in portions at all of the angles θ_{c} when the duty ratio increases as the angle's absolute value |θ_{c}| increases. In this case, the reference line N is the straight line passing through the fixed point C and the portion where the duty ratio is the lowest. Examples thereof include an acoustic wave device in which an IDT electrode provided on a substrate that is made of only −4° rotated Y-cut X propagation LiNbO₃ is embedded in a thick SiO₂ film. Alternatively, the duty ratio is not necessarily the highest or lowest in the excitation portion where the angle θ_{c} is about 0°, through which the reference line N passes.

Next, the dimension of each offset electrode along the direction from its proximal end portion to its distal end portion is referred to as offset electrode length. In the first example embodiment, the impedance ratio was calculated for each change in offset electrode length. The offset electrode length was changed in increments of about 0.5λ in a range not less than about 1λ and not higher than about 5λ. The results thereof will be described below.

FIG. 16 is a diagram illustrating the relationship between the offset electrode length and the impedance ratio.

FIG. 16 reveals that the impedance ratio is greater than or equal to about 71 dB when the offset electrode length is greater than or equal to about 1.5λ and less than or equal to about 5λ. An auxiliary line E in FIG. 16 is a line that connects the plot with an offset electrode length of 1λ and the plot with an offset electrode length of about 1.5λ. As indicated by the auxiliary line E, the impedance ratio is higher than or equal to about 71 dB when the offset electrode length is greater than or equal to about 1.3λ. The offset electrode length is, for example, preferably greater than or equal to about 1.3λ, more preferably greater than or equal to about 1.5λ. This can increase the impedance ratio and improve the Q characteristics of the main mode. On the other hand, the offset electrode length is preferably less than or equal to about 5λ. This can increase the impedance ratio and improve the Q characteristics of the main mode.

This is because of the following reasons. As illustrated in FIG. 3, the angle θ_{c} between the reference line N and the straight line passing through the fixed point C and the edge portion of the intersecting region D on the first busbar 14 side is the intersection angle θ_{c_AP1}. The straight line passing through the edge portion and the fixed point C and the virtual line connecting the plural gaps G1 extend in parallel or substantially in parallel. Therefore, the direction in which the virtual line connecting the plural gaps G1 is transverse to the direction in which the reference line N extends. The direction in which the propagation axis of the piezoelectric layer 6 extends is the X propagation direction and is parallel or substantially parallel to the direction in which the reference line N extends. Acoustic waves excited in the intersecting region D therefore tend to leak from the plural gaps G1.

In contrast, in the case where the first offset electrodes 18 are long enough, such as, for example, about 1.3λ or longer, leaked acoustic waves are reflected on the sufficient number of pairs of first offset electrodes 18 and first electrode fingers 16. The acoustic waves can be thereby effectively confined within the intersecting region D. In a similar manner, acoustic waves leaked from the plural gaps G2 can be reflected toward the intersecting region D on the sufficient number of pairs of second offset electrodes 19 and second electrode fingers 17. The acoustic wave device 1 thus improves in Q characteristics of the main mode.

As illustrated in FIG. 1, the plural first offset electrodes 18 are arc-shaped in the first example embodiment. The duty ratio decreases toward the first busbar 14 in a portion of the IDT electrode 8 where the plural first offset electrodes 18 are provided. In a similar manner, the plural second offset electrodes 19 are arc-shaped. The duty ratio decreases toward the second busbar 15 in a portion of the IDT electrode 8 where the plural second offset electrodes 19 are provided. The plural first offset electrodes 18 and the plural second offset electrodes 19 may be linear. The duty ratio may be constant in the portions where the plural first offset electrodes 18 and the plural second offset electrodes 19 are provided.

Herein, the dimension of the gaps along the direction in which the distal end portions of the electrode fingers and the busbar face each other is referred to as gap width. The gap width in the first example embodiment is synonymous with the dimension of the gaps along the direction in which the distal end portions of the electrode fingers and the distal end portions of the offset electrodes face each other. The impedance ratio was calculated for each change in the gap width. The results thereof will be described below.

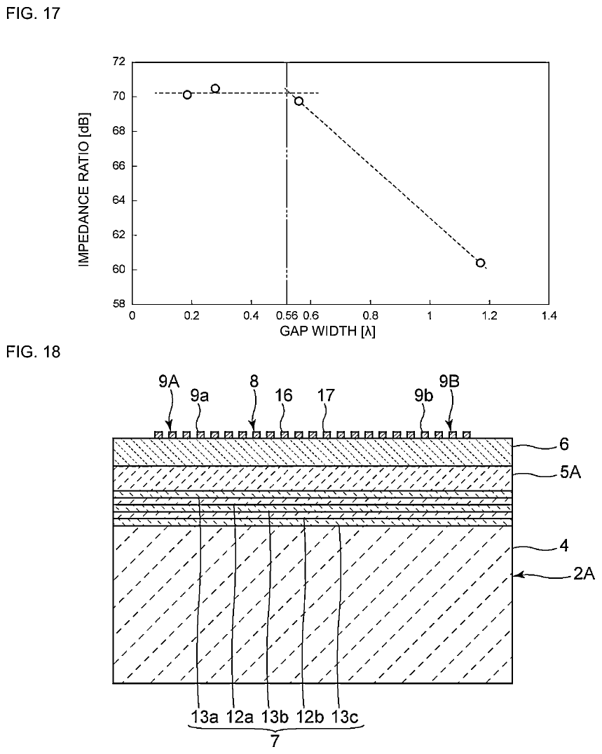

FIG. 17 is a diagram illustrating the relationship between the gap width and the impedance ratio.

FIG. 17 reveals that the impedance ratio is about 70 dB when the gap width is less than or equal to about 0.56λ. The gap width is therefore, for example, preferably less than or equal to about 0.56λ. This can increase the impedance ratio and improve the Q characteristics.

As illustrated in FIG. 2, the piezoelectric substrate 2 is a laminate substrate including the support substrate 4, the first and second layers 5a and 5b of the dielectric layer 5, and the piezoelectric layer 6 in the first example embodiment. In more detail, the first layer 5a in the first example embodiment is a high-velocity film. The high-velocity film is a layer with relatively high acoustic velocity. Specifically, the acoustic velocity of bulk waves propagating in such a high-velocity film is higher than that of acoustic waves propagating in the piezoelectric layer 6. On the other hand, the second layer 5b is a low-velocity film. The low-velocity film is a layer with relatively low acoustic velocity. Specifically, the acoustic velocity of bulk waves propagating in such a low-velocity film is lower than that of bulk waves propagating in the piezoelectric layer 6.

In the piezoelectric substrate 2 of the first example embodiment, the high-velocity film, the low-velocity film and the piezoelectric layer 6 are stacked on top of each other in this order. The energy of acoustic waves can thus be confined in the piezoelectric layer 6 side. The design parameters of the acoustic wave device 1 according to comparative examples illustrated in FIGS. 7 and 8 include examples of the materials of the layers of the piezoelectric substrate 2 and the IDT electrode 8 in the acoustic wave device 1. However, the materials of these layers are not limited to the above-described materials. The combination of the materials of the layers of the piezoelectric substrate 2 and the IDT electrode 8 may be a proper combination of materials to excite acoustic waves.

Examples of the material of the high-velocity film are piezoelectric materials such as aluminum nitride, lithium tantalate, lithium niobate, or quartz, ceramics such as silicon carbide, silicon nitride, sapphire, alumina, zirconia, cordierite, mullite, steatite, forsterite, magnesia, spinel, or sialon, dielectrics such as aluminum oxide, oxynitride silicon, diamond-like carbon (DLC) film, or diamond, and semiconductors such as silicon, polycrystalline silicon, or amorphous silicon, and materials including these materials as a main component.

Examples of the material of the low-velocity film are glass, silicon oxide, silicon oxynitride, lithium oxide, tantalate peroxide, or materials including compounds of silicon oxide added with fluorine, carbon, or boron as the main component.

Examples of the material of the piezoelectric layer 6 are lithium tantalate, lithium niobate, zinc oxide, aluminum nitride, quarts, or lead zirconate titanate (PZT). The material of the piezoelectric layer 6 is, for example, preferably lithium tantalate or lithium niobate.

Examples of the material of the support substrate 4 are piezoelectric materials such as aluminum nitride, lithium tantalate, lithium niobate, or quartz, ceramics such as alumina, sapphire, magnesia, silicon nitride, silicon carbide, zirconia, cordierite, mullite, steatite, forsterite, spinel, or sialon, dielectrics such as aluminum oxide, oxynitride silicon, diamond-like carbon (DLC), or diamond, and semiconductors such as silicon, and materials including the aforementioned materials as the main component. The spinel described as an example of the materials of the support substrate 4 and the high-velocity film includes, for example, an aluminum compound including oxygen and one or more elements of Mg, Fe, Zn, Mn, or other elements. Examples of such spinel are MgAl₂O₄, FeAl₂O₄, ZnAl₂O₄, or MnAl₂O₄. The material of the support substrate 4 is, for example, preferably silicon.

In this specification, the main component refers to a component that includes about 50 wt % or more. The material of the main component may exist, for example, in a single-crystal, polycrystalline, or amorphous form, or a mixed form thereof.

The relationship between velocities in the first layer 5a and the second layer 5b of the dielectric layer 5 is not limited to the above. Furthermore, the layer structure of the piezoelectric substrate 2 is not limited to the above. Hereinafter, third and fourth modifications of the first example embodiment will be described. The third and fourth modifications are different from the first example embodiment only in the configuration of the piezoelectric substrate 2. In the third and fourth modifications, it is possible to reduce or prevent unwanted waves and reduce or prevent deterioration of the resonance characteristics, similar to the first example embodiment. Furthermore, it is possible to effectively confine the energy of acoustic waves in the piezoelectric layer 6 side.

In the third modification illustrated in FIG. 18, a piezoelectric substrate 2A includes the support substrate 4, an acoustic reflective film 7, a dielectric layer 5A, and the piezoelectric layer 6. The acoustic reflective film 7 is provided on the support substrate 4. The dielectric layer 5A is provided on the acoustic reflective film 7. The piezoelectric layer 6 is provided on the dielectric layer 5A. The dielectric layer 5A is a low-velocity film.

The acoustic reflective film 7 is a laminate of plural acoustic impedance layers. Specifically, the acoustic reflective film 7 includes plural low acoustic impedance layers and plural high acoustic impedance layers. The high acoustic impedance layers are layers with relatively high acoustic impedance. More specifically, the plural high acoustic impedance layers of the acoustic reflective film 7 are a high acoustic impedance layer 13a, a high acoustic impedance layer 13b, and a high acoustic impedance layer 13c. The low acoustic impedance layers are layers with relatively low acoustic impedance. More specifically, the plural low acoustic impedance layers of the acoustic reflective film 7 are a low acoustic impedance layer 12a and a low acoustic impedance layer 12b. The low acoustic impedance layers and the high acoustic impedance layers are alternately stacked on top of each other. The high acoustic impedance layer 13a is the closest layer to the piezoelectric layer 6 in the acoustic reflective film 7.

The acoustic reflective film 7 includes, for example, two low acoustic impedance layers and three high acoustic impedance layers. The acoustic reflective film 7 needs to include at least one low acoustic impedance layer and at least one high acoustic impedance layer.

Examples of the material of the low-acoustic impedance layer are silicon oxide or aluminum. Example of the high-acoustic impedance layer are metal such as platinum or tungsten and dielectrics such as aluminum nitride or silicon nitride. The material of the dielectric layer 5A may be the same as the material of the low acoustic impedance layers.

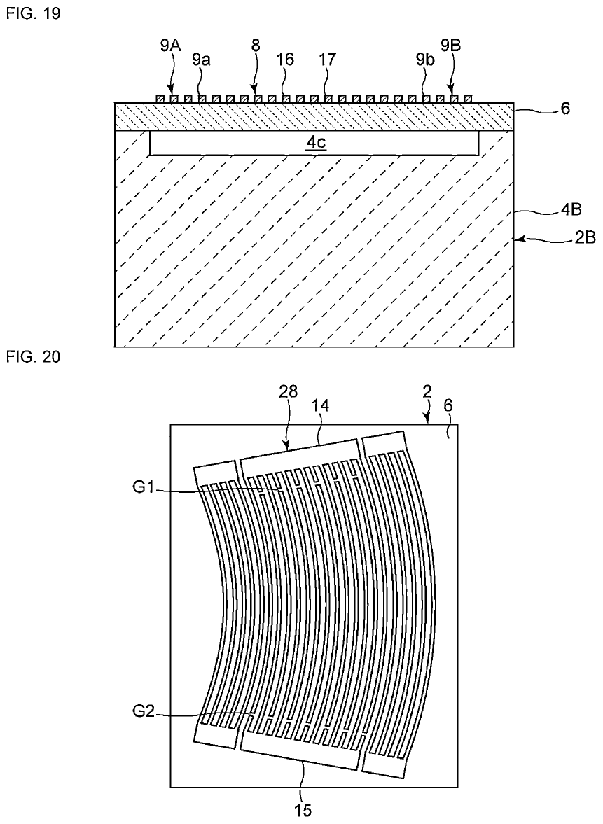

In the fourth modification illustrated in FIG. 19, a piezoelectric substrate 2B includes a support substrate 4B and the piezoelectric layer 6. The piezoelectric layer 6 is provided directly on the support substrate 4B. More specifically, the support substrate 4B includes a recess portion 4c. The piezoelectric layer 6 is provided on the support substrate 4B to cover the recess portion 4c. The piezoelectric substrate 2B thus includes a hollow portion. The hollow portion overlaps at least a portion of the IDT electrode 8 in plan view.

Hereinafter, examples other than the first example embodiment of the present invention will be illustrated. Each example below is different from the first example embodiment in the IDT electrode shape and in the reflector shape accordingly.

FIG. 20 is a schematic plan view of an acoustic wave device according to a second example embodiment of the present invention.

The second example embodiment is different from the first example embodiment in that the shape of the plural electrode fingers in plan view is an elliptical arc. The second example embodiment is also different from the first example embodiment in that the duty ratio in an IDT electrode 28 is constant and the electrode finger pitch is not constant. The acoustic wave device of the second example embodiment includes the same or substantially the same configuration as the acoustic wave device 1 of the first example embodiment other than the above-described differences.

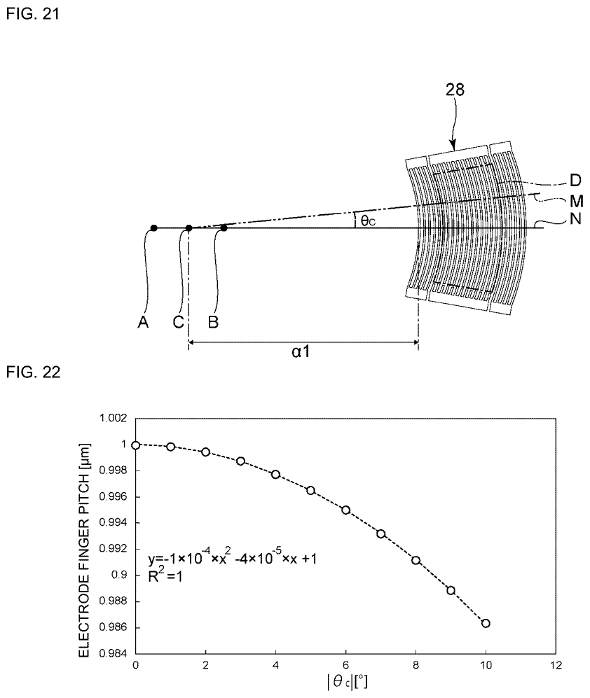

The shapes of the plural electrode fingers in plan view correspond to respective elliptical arcs in plural ellipses whose centers of gravity are located at the same or substantially the same position. In more detail, the center of gravity of each ellipse is the midpoint between focal points A and B illustrated in FIG. 21. When the center of gravity is the fixed point C, the region where straight lines passing through the fixed point C cross electrode fingers adjacent to each other is the intersecting region D. In the second example embodiment, the elliptical coefficient α2/α1<1. More specifically, for example, α2/α1=about 0.72. However, the elliptical coefficient α2/α1 is not limited to the above.

FIG. 22 is a diagram illustrating the relationship between the angle's absolute value |θ_{c}| and the electrode finger pitch in the IDT electrode according to the second example embodiment.

In the IDT electrode 28 of the second example embodiment, the electrode finger pitch is about 1 μm in a portion where the angle θ_{c} is about 0° as illustrated in FIG. 22. The electrode finger pitch decreases as the angle's absolute value |θ_{c}| increases. More specifically, in the second example embodiment, the following equation holds: y=−1×10⁻⁴×x²−4×10⁻⁵×x+1 where x is the angle's absolute value |θ_{c}| and y is the duty ratio. This allows the resonant frequencies to be the same or substantially the same at any angle θ_{c} within the intersecting region D.

In the second example embodiment, it is possible to reduce or prevent unwanted waves and reduce or prevent deterioration of the resonance characteristics, similar to the first example embodiment. In the second example embodiment, it is also possible to reduce or prevent higher-order modes in addition to transverse modes and Rayleigh waves. This advantageous effect will be described in detail below. The second example embodiment will be compared with the first comparative example illustrated in FIG. 6.

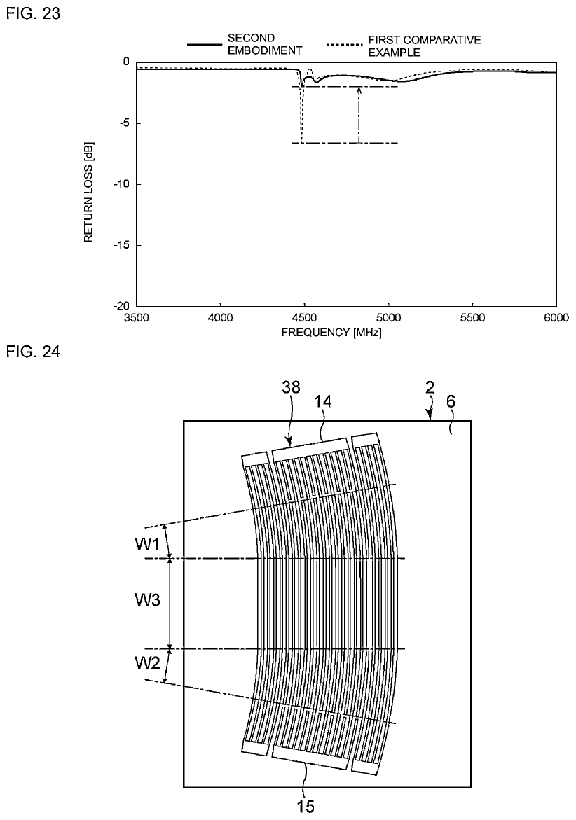

FIG. 23 is a diagram illustrating return loss around frequencies at which higher-order modes occur in the second example embodiment and the first comparative example.

FIG. 23 reveals that higher-order modes are reduced or prevented in the second example embodiment compared to the first comparative example. More specifically, in the second example embodiment, higher-order modes around twice the frequency at which the main mode is excited can be reduced or prevented. This is because the not-constant electrode finger pitch leads to dispersion of frequencies at which modes other than the main mode occur. In the second example embodiment, the resonant frequencies are the same or substantially the same as described above, and the main mode occurs at a constant or substantially constant frequency, reducing or preventing deterioration of the resonance characteristics.

In the second example embodiment, the slowness curve is convex, similar to the first example embodiment. On the other hand, the slowness curve is concave in the acoustic wave device including the IDT electrode on the first piezoelectric substrate according to the comparison in FIG. 9. The first piezoelectric substrate is, for example, a substrate made of only 42° rotated Y-cut X-propagation LiTaO₃. In such a configuration, when the duty ratio is constant and the frequencies are made the same or substantially the same at each angle θ_{c} in similar manner to the second example embodiment, the electrode finger pitch decreases as the absolute value of the angle θ_{c} increases. In the case where the slowness curve is concave, therefore, if the electrode fingers have such a curved shape that the electrode finger pitch increases as the absolute value of the angle θ_{c} increases, the frequencies cannot be matched at each angle θ_{c} by only varying the electrode finger pitch, resulting in deterioration of the resonance characteristics. In contrast, frequencies can be made the same or substantially the same by decreasing the electrode finger pitch as the absolute value of the angle θ_{c} increases, thus improving the characteristics.

In, for example, an acoustic wave device in which an IDT electrode provided on the substrate made of only −4° rotated Y-cut X-propagation LiNbO₃ is embedded in a thick SiO₂ film, the slowness curve is convex. The thickness of the SiO₂ film is about 0.01λ to about 1λ, for example. In this case, the frequencies can be made the same or substantially the same by keeping the duty ratio constant and increasing the electrode finger pitch as the absolute value of the angle θ_{c} increases. The characteristics are thus improved.

Alternatively, for example, in an acoustic wave device in which an IDT electrode provided on a substrate made of only 128.5° rotated Y-cut X-propagation LiNbO₃ is embedded in a thick SiO₂ film, the slowness curve is convex. The thickness of the SiO₂ film is about 0.01λ to about 1λ, for example. In this case, similar to the second example embodiment, frequencies can be made the same or substantially the same by keeping the duty ratio constant and decreasing the electrode finger pitch as the absolute value of the angle θ_{c} increases. The characteristics are thus improved.

Thus, for example, in the cases where the slowness curve is convex in a piezoelectric substrate, the following configurations of the plural first electrode fingers 16 and the plural second electrode fingers 17 can reduce or prevent unwanted waves and reduce or prevent deterioration of the resonance characteristics. That is, the plural first electrode fingers 16 and the plural second electrode fingers 17 need to have one of the following configurations: a configuration in which the electrode finger pitch increases as the absolute value of the angle θ_{c} increases or the configuration in which the electrode finger pitch decreases as the absolute value of the angle θ_{c} increases. The cases where the slowness curve in the piezoelectric substrate is convex include a case where the piezoelectric substrate is a substrate made of only a piezoelectric layer made of lithium niobate.

Alternatively, the slowness curve of the piezoelectric substrate 2 is convex when the piezoelectric substrate 2 is a substrate including a stack of the piezoelectric layer 6 and the support substrate 4 as illustrated in FIG. 2. The slowness curve of the piezoelectric substrate 2 is convex irrespective of whether the piezoelectric layer 6 and the support substrate 4 are directly stacked or indirectly stacked with the dielectric layer 5 interposed therebetween. In this case, examples of the material of the piezoelectric layer 6 are lithium tantalate or lithium niobate.

FIG. 24 is a schematic plan view of an acoustic wave device according to a third example embodiment of the present invention.

The third example embodiment is different from the first example embodiment in that plural electrode fingers of an IDT electrode 38 include linear portions. The acoustic wave device of the third example embodiment has the same or substantially the same configuration as the acoustic wave device 1 of the first example embodiment other than the above-described difference.

The intersecting region of the IDT electrode 38 includes a first area W1, a second area W2, and a third area W3. The first, second, and third areas W1, W2, and W3 are aligned in the direction where the first busbar 14 and the second busbar 15 face each other. More specifically, the first area W1 and the second area W2 face each other across the third area W3. The first area W1 is located on the first busbar 14 side. The second area W2 is located on the second busbar 15 side. The third area W3 includes the portion where the angle θ_{c} is about 0°.

In the first and second areas W1 and W2, the shape of the plural electrode fingers in plan view is an elliptical arc. In the third area W3, the shape of the plural electrode fingers in plan view is linear. Thus, each electrode finger includes portions whose shapes vary in curvature in plan view.

In the second example embodiment, in the entire or substantially the entire third area W3, the direction (the X propagation direction) in which the propagation axis of the piezoelectric layer 6 extends is perpendicular or substantially perpendicular to the direction in which the plural electrode fingers extend. The third area W3 is therefore stable for the propagation axis. The third area W3 being included in the intersecting region reduces or prevents deterioration of the fractional bandwidth.

In the second example embodiment, the resonant frequencies are the same or substantially the same at any angle θ_{c} within the intersecting region D, similar to the first example embodiment. In addition, the plural electrode fingers have different lengths. Furthermore, the portions that are arc-shaped in plan view have different curvatures across the plural electrode fingers. It is therefore possible to reduce or prevent unwanted waves and reduce or prevent deterioration of the resonance characteristics.

In the second example embodiment, each electrode finger includes a linear portion. Even when the electrode fingers do not include any linear portion, each electrode finger may include portions whose shapes vary in curvature in plan view. In this case, preferably, the curvature of the electrode fingers gradually changes as the absolute value of the angle θ_{c} increases. The electric characteristics of the acoustic wave device are thus less likely to deteriorate.

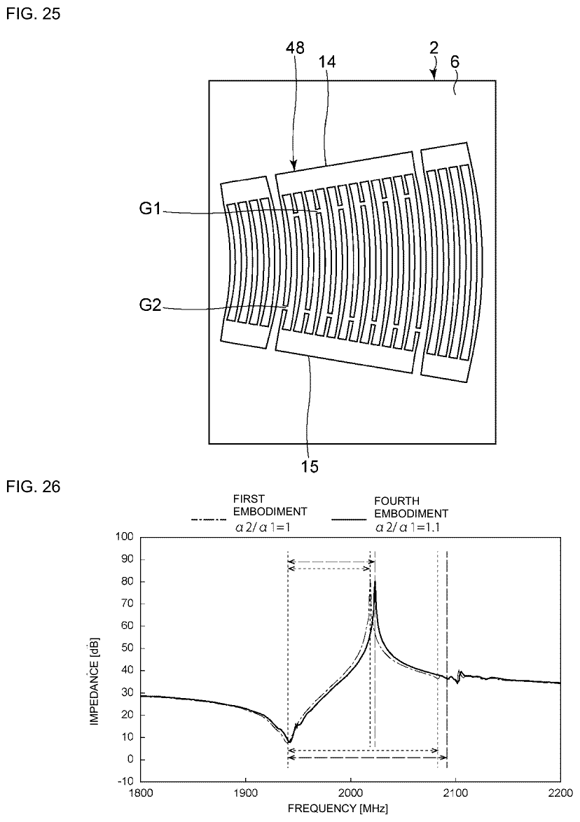

FIG. 25 is a schematic plan view of an acoustic wave device according to a fourth example embodiment of the present invention.

The fourth example embodiment is different from the first example embodiment in that in an IDT electrode 48, the electrode finger pitch is not constant and the elliptical coefficient α2/α1 is greater than about 1. The acoustic wave device of the fourth example embodiment has the same or substantially the same configuration as the acoustic wave device 1 of the first example embodiment other than the above-described differences. In the fourth example embodiment, neither the duty ratio nor the electrode finger pitch is constant.

More specifically, the electrode finger pitch increases as the absolute value of the angle θ_{c} increases in the fourth example embodiment. On the other hand, the duty ratio decreases as the absolute value of the angle θ_{c} increases. This allows the resonant frequencies or anti-resonant frequencies to be the same or substantially the same at any angle θ_{c} within the intersecting region D. In the fourth example embodiment, it is possible to reduce or prevent unwanted waves and reduce or prevent deterioration of the resonance characteristics, similar to the first example embodiment.

In the fourth example embodiment, furthermore, it is possible to increase the value of fractional bandwidth, increase the value of fractional stop-band width, and reduce or prevent responses at the upper end of the stop-band. The fractional bandwidth is expressed by |fr−fa|/fr where fr is the resonant frequency and fa is the anti-resonant frequency. The stop-band is a region in which acoustic waves are confined in a metal grating having a periodic structure and have a constant wavelength. The fractional stop-band width is the bandwidth of the stop band divided by the resonant frequency fr. In this specification, the end of the stop-band on the high-frequency side is referred to as the upper end. The bandwidth of the stop-band is the difference between the frequency at the upper end of the stop-band and the resonant frequency fr.

As the details of the above-described advantageous effects, the impedance-frequency characteristics and return loss will be illustrated. The design parameters of the acoustic wave device of the fourth example embodiment are as follows. The results of the first example embodiment will be illustrated for reference. The design parameters of the acoustic wave device 1 of the first example embodiment are the same as those for the relationship illustrated in FIG. 5 described above.
Number of pairs of electrode fingers of the IDT electrode: 60 pairs
Elliptical coefficient α2/α1 of the shape of electrode fingers: about 1.1
Length of offset electrodes: about 3.5λ
Intersection angle: θ_{c_AP1}, about 10°; θ_{c_AP2}, about −10°
Number of pairs of electrode fingers of reflectors: 20 pairs

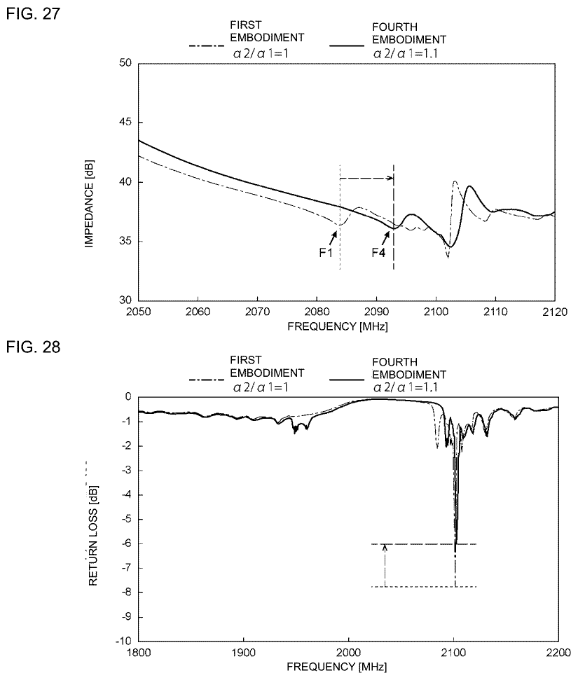

FIG. 26 is a diagram illustrating impedance-frequency characteristics in the first and fourth example embodiments. FIG. 27 is a diagram illustrating impedance-frequency characteristics around the upper end of the stop-band in the first and fourth example embodiments. FIG. 28 is a diagram illustrating return loss in the first and fourth example embodiments.

As illustrated in FIG. 26, the difference between the resonant frequency and the anti-resonant frequency is increased in the fourth example embodiment. This reveals that the fractional bandwidth is increased. Arrow F1 in FIG. 27 indicates a response at the upper end of the stop-band in the first example embodiment. Arrow F4 in FIG. 27 indicates a response at the upper end of the stop-band in the fourth example embodiment. As illustrated in FIG. 27, the frequency of the response at the upper end of the stop-band is higher in the fourth example embodiment than in the first example embodiment. On the other hand, as illustrated in FIG. 26, the resonant frequency in the fourth example embodiment is the same or substantially the same as that in the first example embodiment. Therefore, the value of the fractional stop-band width is also greater in the fourth example embodiment than in the first example embodiment.

In addition, FIG. 28 reveals that the response at the upper end of the stop-band can be reduced or prevented in the fourth example embodiment. The elliptical coefficient α2/α1 of the shape of the plural electrode fingers is greater than about 1 in the fourth example embodiment. This leads to dispersion of the upper-end frequency of the stop-band, thus reducing or preventing the response at the upper-end frequency of the stop-band.

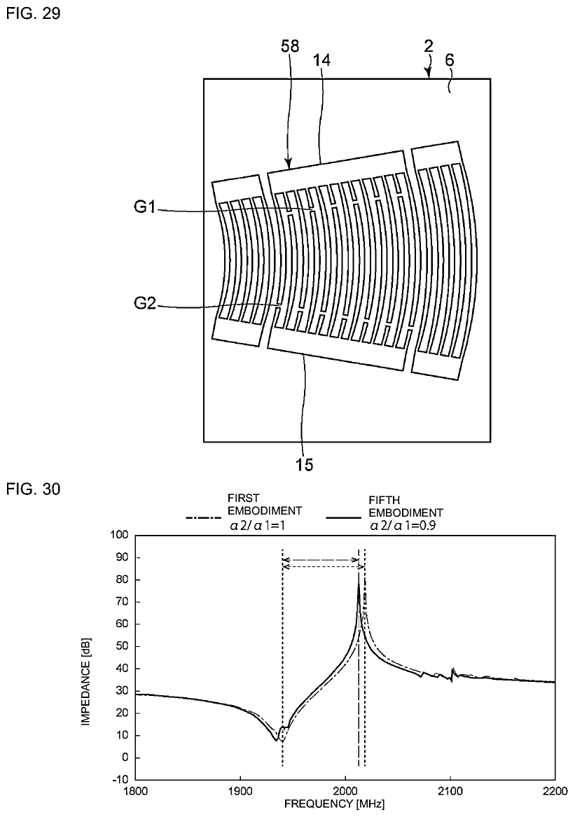

FIG. 29 is a schematic plan view of an acoustic wave device according to a fifth example embodiment of the present invention.

The fifth example embodiment is different from the first example embodiment in that in an IDT electrode 58, the electrode finger pitch is constant and the elliptical coefficient α2/α1 is, for example, smaller than about 1. The acoustic wave device of the fifth example embodiment has the same or substantially the same configuration as the acoustic wave device 1 of the first example embodiment other than the above-described differences. In the fifth example embodiment, neither the duty ratio nor the electrode finger pitch is constant.

More specifically, the electrode finger pitch decreases as the absolute value of the angle θ_{c} increases in the fifth example embodiment. On the other hand, the duty ratio increases as the absolute value of the angle θ_{c} increases. This allows the resonant frequencies or anti-resonant frequencies to be the same or substantially the same at any angle θ_{c} within the intersecting region D. In the fifth example embodiment, it is possible to reduce or prevent unwanted waves and reduce or prevent deterioration of the resonance characteristics, similar to the first example embodiment.

In the fifth example embodiment, furthermore, it is possible to reduce the value of the fractional bandwidth, effectively reducing or preventing higher-order modes, and reducing or preventing responses at the upper end of the stop-band. As the details of the above-described advantageous effects, the impedance-frequency characteristics and return loss will be illustrated. The design parameters of the acoustic wave device of the fifth example embodiment are as follows. The results of the first example embodiment will also be illustrated together for reference. The design parameters of the acoustic wave device 1 of the first example embodiment are the same as those for the relationship illustrated in FIG. 5 described above.
Number of pairs of electrode fingers of the IDT electrode: 60 pairs
Elliptical coefficient α2/α1 of the shape of electrode fingers: about 0.9
Length of offset electrodes: about 3.5λ
Intersection angle: θ_{c_AP1}, about 10°; θ_{c_AP2}, about −10°
Number of pairs of electrode fingers of reflectors: 20 pairs

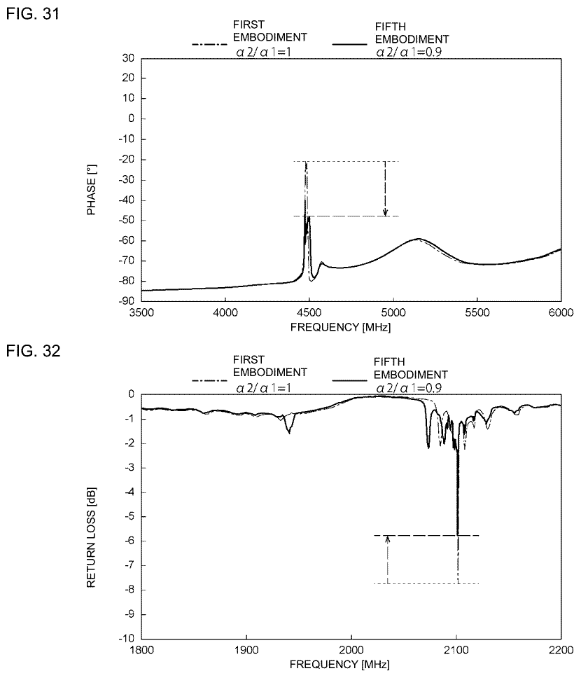

FIG. 30 is a diagram illustrating impedance-frequency characteristics in the first and fifth example embodiments. FIG. 31 is a diagram illustrating phase characteristics around 2.2 times the resonant frequency in the first and fifth example embodiments. FIG. 32 is a diagram illustrating return loss in the first and fifth example embodiments.

As illustrated in FIG. 30, the difference between the resonant frequency and the anti-resonant frequency is reduced in the fifth example embodiment. This reveals that the fractional bandwidth is reduced. As illustrated in FIG. 31, according to the fifth example embodiment, it is possible to effectively reduce or prevent higher-order modes occurring around 2.2 times the resonant frequency.

In addition, FIG. 32 reveals that the response at the upper end of the stop-band can be reduced or prevented in the fifth example embodiment. The elliptical coefficient α2/α1 of the shape of the plural electrode fingers is, for example, smaller than about 1 in the fifth example embodiment. This leads to dispersion of the upper-end frequency of the stop-band. It is therefore possible to reduce or prevent the response at the upper-end frequency of the stop-band.

In the first to fifth example embodiments, the duty ratio or the electrode finger pitch is adjusted to allow the resonant frequencies or anti-resonant frequencies to be the same or substantially the same at each angle θ_{c} within the intersecting region D. However, the thickness of the plural electrode fingers may be adjusted to allow the resonant frequencies or anti-resonant frequencies to be the same or substantially the same at each angle θ_{c} within the intersecting region D. Such an example is illustrated as a sixth example embodiment of the present invention.

The sixth example embodiment is different from the first example embodiment in that in the IDT electrode, the duty ratio is constant and the thickness of the plural electrode fingers is not constant. The acoustic wave device of the sixth example embodiment has the same or substantially the same configuration as the acoustic wave device 1 of the first example embodiment other than the above-described differences.

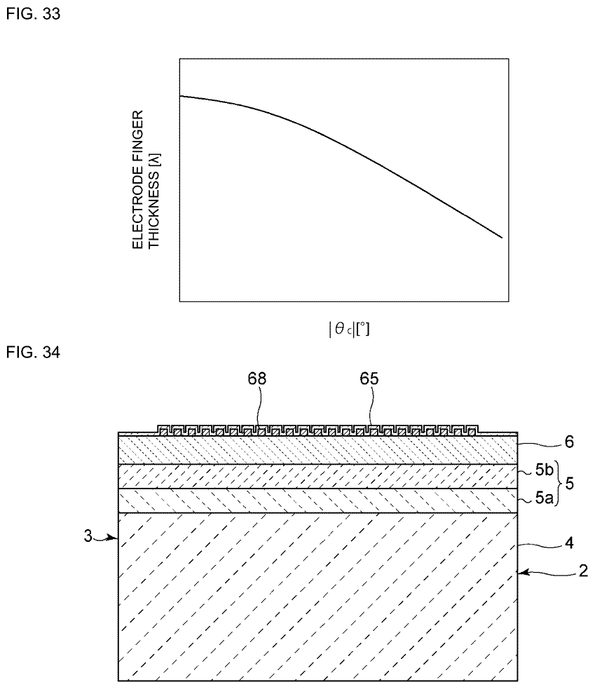

FIG. 33 is a diagram illustrating the relationship between the angle's absolute value |θ_{c}| and the electrode finger thickness in the IDT electrode according to the sixth example embodiment.

In the IDT electrode of the sixth example embodiment, the thickness of electrode fingers decreases as the angle's absolute value |θ_{c}| increases as illustrated in FIG. 33. This allows the resonant frequencies to be the same or substantially the same at any angle θ, within the intersecting region D.

In the sixth example embodiment, in addition, the plural electrode fingers have different lengths, the same as or similar to the first example embodiment. Furthermore, the portions that are arc-shaped in plan view have different curvatures across the plural electrode fingers. It is therefore possible to reduce or prevent unwanted waves and reduce or prevent deterioration of the resonance characteristics.

In the first to sixth example embodiment, the resonant frequencies or anti-resonant frequencies are the same or substantially the same at each angle θ_{c} within the intersecting region D due to the configuration of the IDT electrode. However, the thickness of the dielectric film that covers the IDT electrode may be adjusted to allow the resonant frequencies or anti-resonant frequencies to be the same or substantially the same at each angle θ_{c} within the intersecting region D. An example thereof will be illustrated through a seventh example embodiment and a modification thereof.

FIG. 34 is a schematic elevational cross-sectional view of an acoustic wave device of the seventh example embodiment. FIG. 34 is a schematic cross-sectional view along the reference line N.

The seventh example embodiment is different from the first example embodiment in that in the IDT electrode, the electrode finger pitch is constant. The seventh example embodiment is also different from the first example embodiment in that a dielectric film 65 is provided on the piezoelectric layer 6 so as to cover an IDT electrode 68. The acoustic wave device of the seventh example embodiment has the same or substantially the same configuration as the acoustic wave device 1 of the first example embodiment other than the aforementioned differences.

In the seventh example embodiment, the acoustic velocity of transversal waves propagating in the dielectric film 65 is lower than that of the main mode propagating in the dielectric film 65. The thickness of the dielectric film 65 varies according to the angle θ_{c}. Specifically, portions of the dielectric film 65 cover respective portions of the IDT electrode 68. The thickness of each portion of the dielectric film 65 depends on the angle θ_{c} of the portion of the IDT electrode 68 covered with the portion of the dielectric film 65.

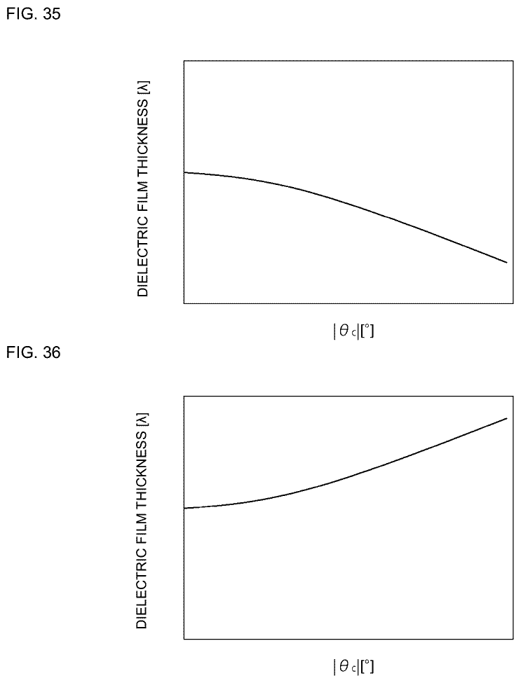

FIG. 35 is a diagram illustrating the relationship between the angle's absolute value |θ_{c}| of portions of the IDT electrode covered with dielectric film and the thickness of the dielectric film in the seventh example embodiment.

In the seventh example embodiment, the thickness of the dielectric film 65 decreases as the angle θ_{c} of the portion of the IDT electrode 68 covered with the dielectric film 65 increases as illustrated in FIG. 35. This allows the resonant frequencies to be the same or substantially the same at any angle θ_{c} within the intersecting region D.

In the seventh example embodiment, in addition, the plural electrode fingers have different lengths, similar to the first example embodiment. Furthermore, the portions that are arc-shaped in plan view have different curvatures across the plural electrode fingers. It is therefore possible to reduce or prevent unwanted waves and reduce or prevent deterioration of the resonance characteristics.

In the seventh example embodiment, the acoustic velocity of transversal waves propagating in the dielectric film 65 is lower than that of the main mode propagating in the dielectric film 65. However, the relationship between acoustic velocities of waves propagating in the dielectric film is not limited to the above. Hereinafter, a modification of the seventh example embodiment will be illustrated, which is different from the seventh example embodiment only in the acoustic velocity of transversal waves propagating in the dielectric film.

In the modification of the seventh example embodiment, the acoustic velocity of transversal waves propagating in the dielectric film is higher than that of the main mode propagating in the dielectric film. In this modification, the relationship between the angle's absolute value |θ_{c}| of portions of the IDT electrode covered with a dielectric film and the thickness of the dielectric film is as illustrated in FIG. 36. More specifically, in this modification, the thickness of the dielectric film increases as the angle θ_{c} of the portion of the IDT electrode covered with the dielectric film increases. This allows the resonant frequencies to be the same or substantially the same at any angle θ_{c} within the intersecting region D. It is therefore possible to reduce or prevent unwanted waves and reduce or prevent deterioration of the resonance characteristics in this modification, similar to the seventh example embodiment.

The first to seventh example embodiments each illustrate a configuration in which the resonant frequencies or anti-resonant frequencies are the same or substantially the same at any angle θ_{c} within the intersecting region D. In example embodiments of the present invention, at least one of the duty ratio, the electrode finger pitch, the thickness of electrode fingers, and the thickness of dielectric film needs to vary according to the angle θ_{c} so that the resonant frequencies or anti-resonant frequencies are the same or substantially the same as described above.

Hereinafter, configuration examples using the piston mode will be illustrated based on eighth to 10th example embodiments of the present invention. In the eighth to 10th example embodiments, it is possible to reduce or prevent unwanted waves and inhibit deterioration of the resonance characteristics, similar to the first example embodiment, and especially transverse modes can be further reduced or prevented.

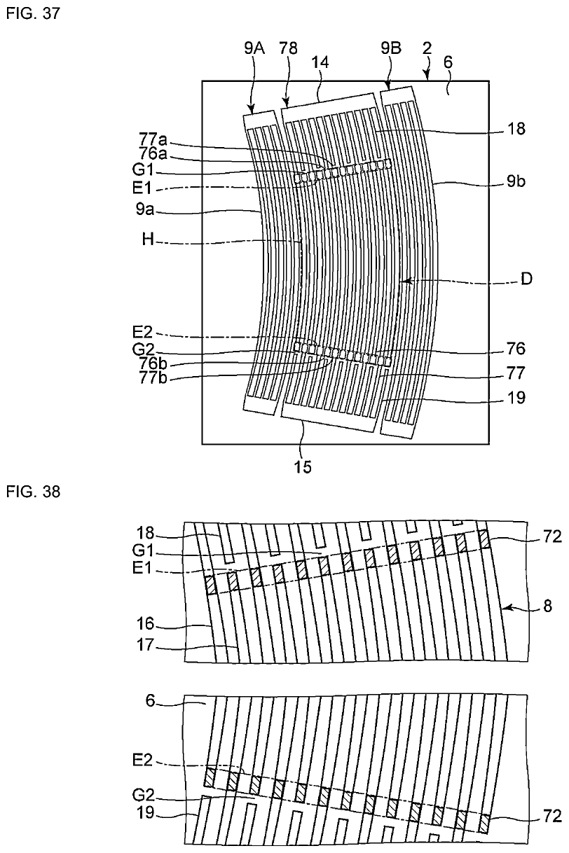

FIG. 37 is a schematic plan view of an acoustic wave device according to the eighth example embodiment.

The eighth example embodiment is different from the first example embodiment in that each of the plural electrode fingers includes a wide section. The acoustic wave device of the eighth example embodiment has the same or substantially the same configuration as the acoustic wave device 1 of the first example embodiment other than the above-described difference.

The intersecting region D of an IDT electrode 78 includes a central section H, a first edge section E1, and a second edge section E2. The first and second edge sections E1 and E2 sandwich the central section H in the direction in which the first and second busbars 14 and 15 face each other. The first edge section E1 is positioned on the first busbar 14 side. The second edge section E2 is positioned on the second busbar 15 side.

Each of plural first electrode fingers 76 includes a wide section 76a in the first edge section E1. Each of the plural first electrode fingers 76 includes a wide section 76b in the second edge section E2. In a similar manner, each of plural second electrode fingers 77 includes a wide section 77a in the first edge section E1. Each of the plural second electrode fingers 77 includes a wide section 77b in the second edge section E2. The wide section of each electrode finger is wider than part of the electrode finger located in the central section H.

In the eighth example embodiment, the plural electrode fingers include the wide sections in the first edge section E1. The wide sections form a low-velocity region in the first edge section E1. The low-velocity region is an area where the acoustic velocity is lower than that in the central section H. In a similar manner, the plural electrode fingers include the wide sections in the second edge section E2. The wide sections form a low-velocity region in the second edge section E2. At least one of the plural electrode fingers needs to include a wide section in at least one of the first and second edge sections E1 and E2.

Of the plural first electrode fingers 76 and the plural second electrode fingers 77, only the plural first electrode fingers 76 are provided in the area where the gaps G1 are aligned. This defines a high-velocity region in the same area. In the high-velocity region, the acoustic velocity is higher than that in the central section H. In a similar manner, of the plural first electrode fingers 76 and the plural second electrode fingers 77, only the plural second electrode fingers 77 are provided in the area where the gaps G2 are aligned. This defines a high-velocity region in the same area.

The central section H, the low-velocity region, and the high-velocity region are arranged in this order from the inside of the IDT electrode 78 toward the outside. The piston mode is thus excited, thus further reducing or preventing transverse modes.

FIG. 38 is a schematic plan view of areas around a first edge section and a second edge section in an acoustic wave device according to a ninth example embodiment of the present invention. In FIG. 38, a mass-adding film is indicated by hatching.

The ninth example embodiment is different from the first example embodiment in that mass-adding films 72 are provided on the plural electrode fingers in the first and second edge sections E1 and E2. The acoustic wave device of the ninth example embodiment has the same or substantially the same configuration as the acoustic wave device 1 of the first example embodiment other than the above-described difference.

Specifically, in the ninth example embodiment, the plural mass-adding films 72 are provided in each of the first and second edge sections E1 and E2. In more detail, one of the mass-adding films 72 is provided on each electrode finger, in both the first and second edge sections E1 and E2. Low-velocity regions are thus provided in the first and second edge sections E1 and E2. Such a configuration excites the piston mode and further reduces or prevents transverse modes.

When each mass-adding film 72 does not extend across plural electrode fingers as in the ninth example embodiment, the mass-adding films 72 may be made of proper metal. The mass-adding films 72 may be made of the same type of metal as that of the electrode fingers. In this case, substantially, the electrode fingers are thicker in the first and second edge sections E1 and E2 than in the central section H. However, the mass-adding films 72 may be made of a different type of metal from the electrode fingers or a proper dielectric.

The mass-adding films 72 each may be provided across plural electrode fingers. In this case, the mass-adding films 72 need to be made of a proper dielectric.

In the ninth example embodiment, the piezoelectric layer 6, the electrode fingers, and the mass-adding films 72 are stacked on top of each other in this order but may be stacked in the order of the piezoelectric layer 6, the mass-adding films 72, and the electrode fingers. That is, the mass-adding films 72 may be located between the piezoelectric layer 6 and the electrode fingers. The mass-adding films 72 need to overlap the electrode fingers in plan view. The mass-adding films 72 need to overlap at least one of the electrode fingers in plan view.

The low-velocity regions may be provided by both the configuration of the ninth example embodiment, which includes the mass-adding films 72, and the configuration of the eighth example embodiment, which includes the wide sections.

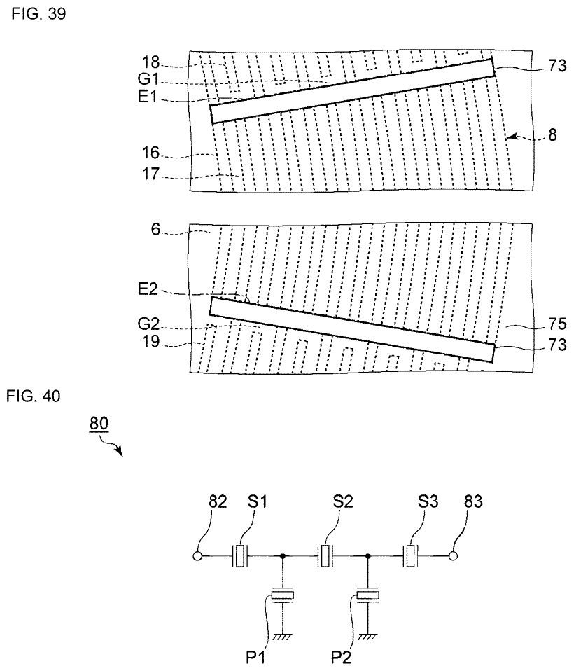

FIG. 39 is schematic plan views of areas around a first edge section and a second edge section in an acoustic wave device according to a 10th example embodiment of the present invention.

The 10th example embodiment is different from the first example embodiment in that a dielectric film 75 is provided on the piezoelectric layer 6 to cover the IDT electrode 8 and plural mass-adding films 73 are provided on the dielectric film 75. The acoustic wave device of the 10th example embodiment has the same or substantially the same configuration as the acoustic wave device 1 of the first example embodiment other than the aforementioned differences.

One of the mass-adding films 73 is provided on the dielectric film 75, in both the first edge section E1 and the second edge section E2. Each mass-adding film 73 is provided so as to overlap plural electrode fingers in plan view. The mass-adding films 73 are made of metal. Low-velocity regions are thus provided in the first and second edge sections E1 and E2. Such a configuration excites the piston mode and further reduces or prevents transverse modes.

The mass-adding films 73 may be made of a proper dielectric. The mass-adding films 73 may be made of the same type of dielectric as the dielectric film 75. In this case, substantially, the dielectric film 75 is thicker in the first and second edge sections E1 and E2 than in the central section H. On the other hand, the mass-adding film 73 may be made of a different type of dielectric from the dielectric film 75. In this case, the dielectric film as a stack is thicker in the first and second edge sections E1 and E2 than in the central section H.

The plural mass-adding films 73 may be provided in each of the first edge section E1 and the second edge section E2.

The low-velocity regions may be provided by both of the configuration of the 10th example embodiment, which includes the dielectric film 75 and the mass-adding films 73, and the configuration of the eighth example embodiment, which includes the wide sections.

An acoustic wave device according to example embodiments of the present invention can be applied to, for example, a filter device. An example thereof will be described below.

FIG. 40 is a circuit diagram of a filter device according to an 11th example embodiment of the present invention.

A filter device 80 of the 11th example embodiment is, for example, a ladder filter. The filter device 80 includes a first signal terminal 82, a second signal terminal 83, plural series arm resonators, and plural parallel arm resonators. In the filter device 80, all of the series arm resonators and all of the parallel arm resonators are acoustic wave resonators. Furthermore, all of the series arm resonators and all of the parallel arm resonators are acoustic wave devices according to example embodiments of the present invention. At least one of the plural acoustic wave resonators of the filter device 80 needs to be an acoustic wave device according to an example embodiment of the present invention.

The first signal terminal 82 is, for example, an antenna terminal. The antenna terminal is coupled to an antenna. However, the first signal terminal 82 is not necessarily an antenna terminal. The first signal terminal 82 and the second signal terminal 83 may be configured as electrode pads or wiring, for example.

The plural series arm resonators of the 11th example embodiment are specifically a series arm resonator S1, a series arm resonator S2, and a series arm resonator S3. The plural series arm resonators are coupled to each other in series between the first signal terminal 82 and the second signal terminal 83. The plural parallel arm resonators are specifically a parallel arm resonator P1 and a parallel arm resonator P2. The parallel arm resonator P1 is coupled between the ground potential and the connecting point between the series arm resonator S1 and the series arm resonator S2. The parallel arm resonator P2 is coupled between the ground potential and the connecting point between the series arm resonator S2 and the series arm resonator S3. The circuit configuration of the filter device 80 is not limited to the above. The filter device 80 may include, for example, a longitudinally coupled resonator acoustic wave filter.

Each acoustic wave resonator of the filter device 80 is an acoustic wave device according to an example embodiment of the present invention. It is therefore possible to reduce or prevent unwanted waves and reduce or prevent deterioration of the resonance characteristics in the acoustic wave resonators of the filter device 80.

In the acoustic wave device according to each example embodiment described above, the curves in the shape of the plural electrode fingers in plan view are smooth curves. The curves in the shape of the plural electrode fingers in plan view may have a shape provided by connecting very small straight lines. The curves in the shape of the plural electrode fingers in plan view may have a shape provided by connecting several vertices with curves. Alternatively, the curves in the shape of the plural electrode fingers in plan view are not necessarily smooth curves. An example thereof will be described as a fifth modification of the first example embodiment of the present invention.

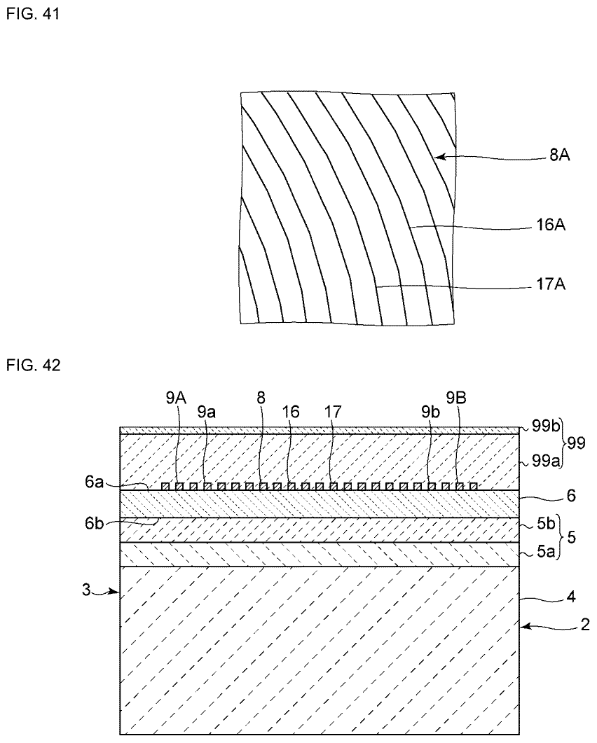

In an IDT electrode 8A of the fifth modification, which is enlarged and illustrated in FIG. 41, the curve of the shape of each first electrode finger 16A in plan view is not smooth. More specifically, the shape of each first electrode finger 16A in plan view is a shape provided by connecting straight lines. The straight lines in this shape are not very small. More specifically, the length of the straight lines in the shape is, for example, about several percent of the entire length of the first electrode fingers 16A. The angle between the connected straight lines in the shape is large enough, for example, such as greater than or equal to about 160° and smaller than about 180°. The shape of each first electrode finger 16A in plan view can therefore be approximated to a curve.

The shape of each second electrode finger 17A in plan view is the same as or similar to the shape of each first electrode finger 16A in plan view. In the fifth modification, it is possible to reduce or prevent unwanted waves and reduce or prevent deterioration of the resonance characteristics, similar to the first example embodiment.

FIG. 42 is a schematic elevational cross-sectional view of an acoustic wave device according to a 12th example embodiment of the present invention.

The 12th example embodiment is different from the first example embodiment in that the IDT electrode 8 is embedded in a protection film 99. The acoustic wave device of the 12th example embodiment has the same or substantially the same configuration as the acoustic wave device 1 of the first example embodiment other than the aforementioned difference.

Specifically, the protection film 99 is provided on the piezoelectric layer 6 so as to cover the IDT electrode 8. The protection film 99 is thicker than the IDT electrode 8. The IDT electrode 8 is embedded in the protection film 99. The IDT electrode 8 is thus less subject to damage.

The protection film 99 includes a first protection layer 99a and a second protection layer 99b. The IDT electrode 8 is embedded in the first protection layer 99a. The second protection layer 99b is provided on the first protection layer 99a. The protection film 99 thus provides multiple advantageous effects. Specifically, the first protection layer 99a is, for example, made of silicon oxide in the 12th example embodiment. This allows the absolute value of the temperature coefficient of frequency (TCF) of the acoustic wave device to be reduced. Thus, the temperature characteristics of the acoustic wave device can be improved. The second protection layer 99b is, for example, made of silicon nitride. This can improve the resistance to humidity of the acoustic wave device.

In addition, the IDT electrode 8 in the 12th example embodiment is configured in the same or similar manner to that in the first example embodiment. It is therefore possible to reduce or prevent unwanted waves and reduce or prevent deterioration of the resonance characteristics.

The materials of the first and second protection layers 99a and 99b are not limited to the above. The protection film 99 may include a single layer or a stack of three layers or more.

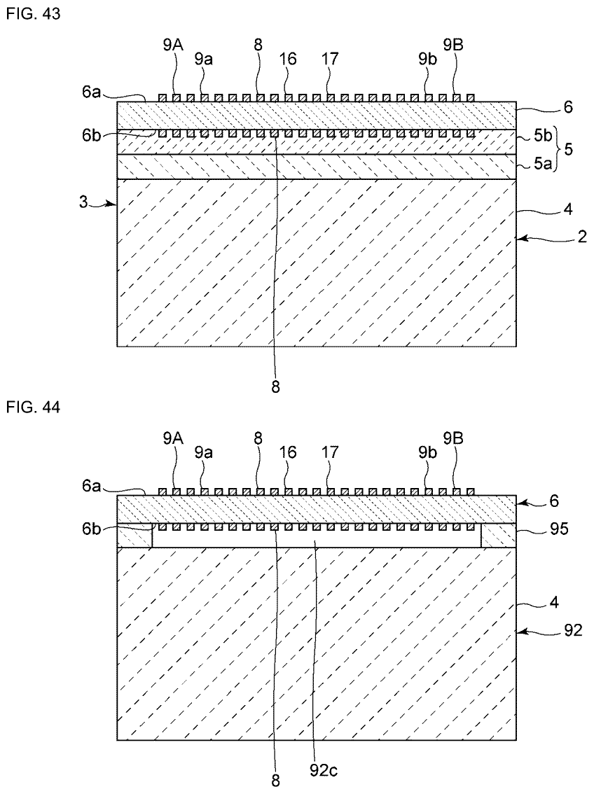

FIG. 43 is a schematic elevational cross-sectional view of an acoustic wave device according to a 13th example embodiment of the present invention.

The 13th example embodiment is different from the first example embodiment in that the IDT electrode 8 is provided on each of a first major surface 6a and a second major surface 6b of the piezoelectric layer 6. The IDT electrode 8 provided on the second major surface 6b is embedded in the second layer 5b of the dielectric layer 5. The acoustic wave device of the 13th example embodiment has the same or substantially the same configuration as the acoustic wave device 1 of the first example embodiment other than the above-described difference.

The IDT electrode 8 provided on the first major surface 6a of the piezoelectric layer 6 and the IDT electrode 8 provided on the second major surface 6b face each other across the piezoelectric layer 6. In the acoustic wave device of the 13th example embodiment, the IDT electrode 8 is provided on the first major surface 6a in the same or similar manner to that in the first example embodiment. It is therefore possible to reduce or prevent unwanted waves and reduce or prevent deterioration of the resonance characteristics.

The IDT electrodes 8 provided on the first and second major surfaces 6a and 6b of the piezoelectric layer 6 may have different design parameters, for example.

Hereinafter, first to third modifications of the 13th example embodiment will be illustrated, including at least one of the following options: the configuration of the electrode provided on the second major surface of the piezoelectric layer or the laminate structure of the piezoelectric substrate is different from that of the 13th example embodiment. In the first to third modifications, it is possible to reduce or prevent unwanted waves and reduce or prevent deterioration of the resonance characteristics, similar to the 13th example embodiment.

In the first modification illustrated in FIG. 44, the layer structure of a piezoelectric substrate 92 is different from that of the 13th example embodiment. Specifically, the piezoelectric substrate 92 includes the support substrate 4, a dielectric layer 95, and the piezoelectric layer 6. The dielectric layer 95 is provided on the support substrate 4. The piezoelectric layer 6 is provided on the dielectric layer 95. In the first modification, the dielectric layer 95 has a frame shape. That is, the dielectric layer 95 includes a through-hole.

The support substrate 4 closes one end of the through-hole of the dielectric layer 95. The piezoelectric layer 6 closes the other end of the through-hole of the dielectric layer 95. A hollow portion 92c is thus provided in the piezoelectric substrate 92. A portion of the piezoelectric layer 6 and a portion of the support substrate 4 face each other across the hollow portion 92c. The IDT electrode 8 provided on the second major surface 6b of the piezoelectric layer 6 is located within the hollow portion 92c.

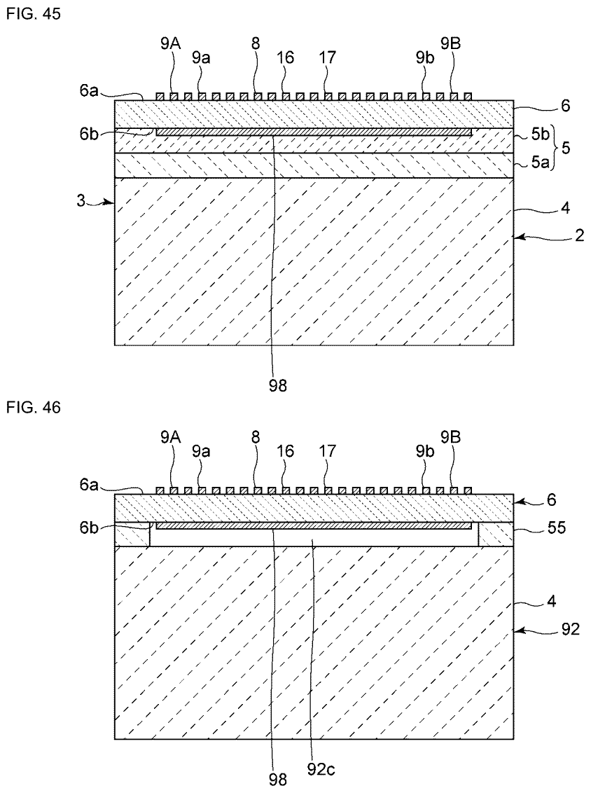

In the second modification illustrated in FIG. 45, a plate-shaped electrode 98 is provided on the second major surface 6b of the piezoelectric layer 6. The IDT electrode 8 and the electrode 98 face each other across the piezoelectric layer 6.

In the third modification illustrated in FIG. 46, the piezoelectric substrate 92 is configured in the same or similar manner to that in the first modification, and the electrode 98, which is the same as or similar to that of the second modification, is provided on the second major surface 6b of the piezoelectric layer 6. The electrode 98 is located within the hollow portion 92c.

The 12th example embodiment, the 13th example embodiment, and the modifications illustrate examples in which the IDT electrode 8 has the same or substantially the same configuration as that of the first example embodiment. However, the configurations of the 12th example embodiment, the 13th example embodiment, and the modifications can be also used when the IDT electrode has the same or substantially the same configuration as the configuration of example embodiments of the present invention other than the first example embodiment.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a piezoelectric substrate including a piezoelectric layer; and
an IDT electrode on the piezoelectric layer; wherein
the IDT electrode includes:
a first busbar and a second busbar facing each other;
a plurality of first electrode fingers each of which includes one end connected to the first busbar; and
a plurality of second electrode fingers each of which includes one end connected to the second busbar;
the plurality of first electrode fingers and the plurality of second electrode fingers are interdigitated with each other;
a portion where the plurality of first electrode fingers and the plurality of second electrode fingers overlap in an acoustic wave propagation direction is an intersecting region;
a shape of the pluralities of first and second electrode fingers in plan view includes a curved portion; and
in the intersecting region, resonant frequencies or anti-resonant frequencies are the same or substantially the same.

2. The acoustic wave device according to claim 1, wherein
the curved portion has a shape of a circular arc or an elliptical arc; and
the resonant frequencies or the anti-resonant frequencies are the same or substantially the same at any angle θ_{c} within the intersecting region, where the angle θ_{c} is an angle between a straight line passing through a fixed point and a reference line, the fixed point being a center of a circle including the circular arc of the shape of the first and second electrode fingers or a midpoint between two foci of an ellipse including the elliptical arc, the reference line being a straight line passing through a center of the intersecting region in a direction in which the pluralities of first and second electrode fingers extend.

3. An acoustic wave device, comprising:
a piezoelectric substrate including a piezoelectric layer; and
an IDT electrode on the piezoelectric layer; wherein
the IDT electrode includes:
a first busbar and a second busbar facing each other;
a plurality of first electrode fingers each of which includes one end connected to the first busbar; and
a plurality of second electrode fingers each of which includes one end connected to the second busbar;
the plurality of first electrode fingers and the plurality of second electrode fingers are interdigitated with each other;
a portion where the plurality of first electrode fingers and the plurality of second electrode fingers overlap in an acoustic wave propagation direction is an intersecting region;
a shape of the pluralities of first and second electrode fingers in plan view includes a shape of a circular arc or an elliptical arc; and
an electrode finger pitch decreases as an absolute value of an angle θ_{c} increases, where the angle θ_{c} is an angle between a straight line passing through a fixed point and a reference line, the fixed point being a center of a circle including the circular arc of the shape of the first and second electrode fingers or a midpoint between two foci of an ellipse including the elliptical arc, the reference line being a straight line passing through a center of the intersecting region in a direction in which the pluralities of first and second electrode fingers extend.

4. The acoustic wave device according to claim 2, wherein the electrode finger pitch varies according to the angle θ_{c} such that resonant frequencies or anti-resonant frequencies are the same or substantially the same at any angle θ_{c} within the intersecting region.

5. The acoustic wave device according to claim 1, wherein the piezoelectric layer includes lithium tantalate or lithium niobate.

6. The acoustic wave device according to claim 1, wherein
the piezoelectric substrate includes a support substrate; and
the piezoelectric layer is provided on the support substrate.

7. The acoustic wave device according to claim 6, wherein
the piezoelectric substrate includes a dielectric layer; and
the dielectric layer is provided between the support substrate and the piezoelectric layer.

8. The acoustic wave device according to claim 6, wherein the support substrate includes silicon.

9. An acoustic wave device, comprising:
a piezoelectric substrate including a piezoelectric layer; and
an IDT electrode on the piezoelectric layer; wherein
the piezoelectric substrate is one of a substrate including a stack of a support substrate and the piezoelectric layer including lithium tantalate or lithium niobate or a substrate including only the piezoelectric layer including lithium niobate;
the IDT electrode includes:
a first busbar and a second busbar facing each other;
a plurality of first electrode fingers each of which includes one end connected to the first busbar; and
a plurality of second electrode fingers each of which includes one end connected to the second busbar;
the plurality of first electrode fingers and the plurality of second electrode fingers are interdigitated with each other;
a portion where the plurality of first electrode fingers and the plurality of second electrode fingers overlap in an acoustic wave propagation direction is an intersecting region;
a shape of the pluralities of first and second electrode fingers in plan view includes a shape of a circular arc or an elliptical arc; and
the pluralities of first and second electrode fingers have one of a configuration in which electrode finger pitch increases as an absolute value of an angle θ_{c} increases or a configuration in which the electrode finger pitch decrease as the absolute value of the angle θ_{c} increases where the angle θ_{c} is an angle between a straight line passing through a fixed point and a reference line, the fixed point being a center of a circle including the circular arc of the shape of the first and second electrode fingers or a midpoint between two foci of an ellipse including the elliptical arc, the reference line being a straight line passing through a center of the intersecting region in a direction in which the pluralities of first and second electrode fingers extend.

10. The acoustic wave device according to claim 3, wherein resonant frequencies or anti-resonant frequencies are the same or substantially the same at any angle θ_{c} within the intersecting region.

11. The acoustic wave device according to claim 1, wherein
the curved portion has a shape of a circular arc or an elliptical arc; and
at least one of a duty ratio or a thickness of the pluralities of first and second electrode fingers varies according to an angle θ_{c} such that resonant frequencies or anti-resonant frequencies are substantially the same at any angle θ_{c} within the intersecting region, where the angle θ_{c} is an angle between a straight line passing through a fixed point and a reference line, the fixed point being a center of a circle including the circular arc of the shape of the first and second electrode fingers or a midpoint between two foci of an ellipse including the elliptical arc, the reference line being a straight line passing through a center of the intersecting region in a direction in which the pluralities of first and second electrode fingers extend.

12. The acoustic wave device according to claim 1, further comprising:
a dielectric film on the piezoelectric layer and covering the IDT electrode; wherein
the curved portion has a shape of a circular arc or an elliptical arc; and
a thickness of the dielectric film varies according to an angle θ_{c} such that resonant frequencies or anti-resonant frequencies are substantially the same at any angle θ_{c} within the intersecting region, where the angle θ_{c} is an angle between a straight line passing through a fixed point and a reference line, the fixed point being a center of a circle including the circular arc of the shape of the first and second electrode fingers or a midpoint between two foci of an ellipse including the elliptical arc, the reference line being a straight line passing through a center of the intersecting region in a direction in which the pluralities of first and second electrode fingers extend.

13. The acoustic wave device according to claim 2, wherein α2/α1>about 1, where α2/α1 is an elliptical coefficient of the shape of the pluralities of the first and second electrode fingers in plan view.

14. The acoustic wave device according to claim 2, wherein α2/α1=about 1 where α2/α1 is an elliptical coefficient of the shape of the pluralities of the first and second electrode fingers in plan view.

15. The acoustic wave device according to claim 2, wherein α2/α1<about 1 where α2/α1 is an elliptical coefficient of the shape of the pluralities of the first and second electrode fingers in plan view.

16. The acoustic wave device according to claim 2, wherein the pluralities of first and second electrode fingers include at least two of the first or second electrode fingers whose shapes vary in curvature in plan view.

17. The acoustic wave device according to claim 16, wherein the curvature of the first and second electrode fingers gradually varies from one side to another in a direction in which the pluralities of first and second electrode fingers are aligned.

18. The acoustic wave device according to claim 2, wherein each of the pluralities of the first and second electrode fingers includes portions whose shapes vary in curvature in plan view.

19. The acoustic wave device according to claim 18, wherein the curvature of the pluralities of the first and second electrode fingers gradually changes as an absolute value of the angle θ_{c} increases.

20. The acoustic wave device according to claim 18, wherein the shape of the pluralities of first and second electrode fingers in plan view includes a linear shape.

21. The acoustic wave device according to claim 1, wherein
the piezoelectric layer includes a piezoelectric single crystal;
the piezoelectric layer includes a propagation axis;
the curved portion has a shape of a circular arc or an elliptical arc; and
the propagation axis and a reference line extend in parallel or substantially in parallel where a fixed point is a center of a circle including the circular arc of the shape of the first and second electrode fingers or a midpoint between two foci of an ellipse including the elliptical arc and the reference line is a straight line passing through a center of the intersecting region in a direction in which the pluralities of first and second electrode fingers extend.

22. The acoustic wave device according to claim 1, wherein
each of distal end portions of the plurality of first electrode fingers faces the second busbar across at least a gap;
the curved portion has a shape of a circular arc or an elliptical arc; and
a direction in which a virtual line connecting the gaps extends is transverse to a direction in which a reference line extends where a fixed point is a center of a circle including the circular arc of the shape of the first and second electrode fingers or a midpoint between two foci of an ellipse including the elliptical arc and the reference line is a straight line passing through a center of the intersecting region in a direction in which the pluralities of first and second electrode fingers extend.

23. The acoustic wave device according to claim 1, wherein
each of distal end portions of the plurality of first electrode fingers faces the second busbar across at least a gap;
the curved portion has a shape of a circular arc or an elliptical arc; and
a dimension of each of the gaps along a direction in which each of the distal end portions of the first electrode fingers faces the second busbar is less than or equal to about 0.56λ where a fixed point is a center of a circle including the circular arc of the shape of the first and second electrode fingers or a midpoint between two foci of an ellipse including the elliptical arc, a reference line is a straight line passing through a center of the intersecting region in a direction in which the pluralities of first and second electrode fingers extend, and A is a wavelength defined by electrode finger pitch in a portion of the IDT electrode through which the reference line passes.

24. The acoustic wave device according to claim 1, wherein
the IDT electrode includes a plurality of first offset electrodes and a plurality of second offset electrodes;
each of the plurality of first offset electrodes is connected to the first busbar and each of the plurality of second offset electrodes is connected to the second busbar; and
distal end portions of the plurality of first electrode fingers face distal end portions of the plurality of second offset electrodes across gaps.

25. The acoustic wave device according to claim 1, wherein
the intersecting region includes a central section, a first edge section, and a second edge section;
the first and second edge sections sandwich the central section in a direction in which the first busbar and the second busbar face each other; and
the pluralities of first and second electrode fingers have at least one of a configuration in which the pluralities of first and second electrode fingers are wider in the first and second edge sections than in the central section or a configuration in which the pluralities of first and second electrode fingers are thicker in the first and second edge sections than in the central section.

26. The acoustic wave device according to claim 1, further comprising:
a dielectric film on the piezoelectric layer and covering the IDT electrode; wherein
the intersecting region includes a central section, a first edge section, and a second edge section;
the first and second edge sections sandwich the central section in a direction in which the first busbar and the second busbar face each other; and
portions of the dielectric film in the first edge section and the second edge section are thicker than a portion of the dielectric film in the central section.

27. The acoustic wave device according to claim 1, further comprising:
a dielectric film on the piezoelectric layer and covering the IDT electrode; wherein
the intersecting region includes a central section, a first edge section, and a second edge section;
the first and second edge sections sandwich the central section in a direction in which the first busbar and the second busbar face each other;
a mass-adding film is provided on portions of the dielectric film in the first and second edge sections and overlaps the pluralities of first and second electrode fingers in plan view; and
the mass-adding film includes metal.

28. A filter device, comprising:
a plurality of acoustic wave resonators; wherein at least one of the plurality of acoustic wave resonators is the acoustic wave device according to claim 1.
